(19) United States
(12) Patent Application Publication
(10) Pub. No.: US 2016/0156309 A1
(43) Pub. Date: Jun. 2, 2016

(54) PHOTOVOLTAIC-THERMAL SOLAR ENERGY COLLECTION SYSTEM WITH ENERGY STORAGE

(71) Applicant: SunPower Corporation, San Jose, CA (US)

(72) Inventors: Gilad ALMOGY, Palo Alto, CA (US); Ratson MORAD, Palo Alto, CA (US); Matthew Dean GOODYEAR, Stanford, CA (US); Mani THOTHADRI, Mountain View, CA (US)

(21) Appl. No.: 14/904,293

(22) PCT Filed: Jul. 11, 2014
(86) PCT No.: PCT/US14/46396

§ 371 Date: Jan. 11, 2016

Related U.S. Application Data
(60) Provisional application No. 61/845,541, filed on Jul. 12, 2013.
(60) Provisional application No. 61/860,720, filed on Jul. 31, 2013.

(51) Int. Cl. H02S 40/44; F03G 6/06; F03G 6/00; H01L 31/052; H02S 40/22

(52) U.S. Cl. CPC H02S 40/44; H01L 31/052; H02S 40/22; F03G 6/001; F03G 6/065

(57) ABSTRACT

Systems, methods, and apparatus by which solar energy may be collected to provide electricity, heat, and/or cold are disclosed herein.

### CROSS REFERENCE TO RELATED APPLICATIONS

This application claims benefit of priority to U.S. Provisional Patent Application No. 61/845,541 titled “Photovoltaic-Thermal Solar Energy Collection System With Energy Storage” and filed on Jul. 12, 2013; and to U.S. Provisional Patent Application No. 61/860,720 titled “Solar Energy Collection System With Energy Storage” and filed on Jul. 31, 2013, both of which are incorporated herein by reference in their entirety.

### FIELD

Described herein are systems, methods and apparatus relating generally to the collection of solar energy to provide electrical energy, thermal energy, or electrical energy and thermal energy.

### BACKGROUND

Solar energy supply is sufficient in many geographical regions to satisfy energy demands, in part, by provision of electric power and useful heat. Solar energy systems may be used to replace or augment traditional energy sources powered by fossil fuel. Improved solar energy systems are needed to satisfy increasing worldwide energy demands. Improved solar energy systems incorporating energy storage are needed. In particular, improved solar energy systems that are capable of delivering substantial dispatchable electrical energy (for example, during low solar output periods or during peak demand times) are desired.

### SUMMARY

Systems, methods, and apparatus in which solar energy is collected and converted to electrical energy, thermal energy, or a combination of electrical energy and thermal energy are described herein. These systems, methods and apparatus may provide solar-generated dispatchable useful work (e.g., electrical energy) as demanded.

Solar energy systems according to a first aspect of the invention comprise a concentrating photovoltaic-thermal solar energy collector capable of generating electrical energy e1 and heat h1 for use in one or more applications. At least a portion of the solar-generated electrical energy e1 may be used to drive a heat pump to draw heat h2 from a cold reservoir. A hot reservoir may be heated at least in part using at least a portion of heat h1 from the photovoltaic-thermal solar energy collector and at least a portion of heat h2 generated by the heat pump. A heat engine may be used to convert thermal energy in the hot reservoir to electrical energy e2. Electrical energy e2 is dispatchable energy that may be used as demanded, for example, during low solar output times, or during high demand times.

Some variations of the systems may be configured or operated so that electrical energy e2 is generated from the hot reservoir at a time delayed relative to the generation of electrical energy e1. For example, thermal energy may be stored for a desired time period in the hot reservoir and, upon demand, the thermal energy in the hot reservoir may be converted to electrical energy e2. In some cases, systems may be configured or operated so electrical energy e2 is generated from thermal energy in the hot reservoir during generation of electrical energy e1 by the photovoltaic-thermal solar energy collector. Some systems may be configured or operated so that electrical energy e2 is generated from thermal energy in the hot reservoir when no electrical energy e1 is being generated by the photovoltaic-thermal solar energy collector.

Any suitable heat engine may be used in the systems to convert thermal energy of the hot reservoir to electrical energy e2. In some cases, the heat engine is or comprises the heat pump run in a reverse direction, so that heat flows from the hot reservoir to the cold reservoir. In some cases, the heat engine comprises an organic Rankine cycle engine. In some variations, the heat engine comprises an organic Rankine cycle engine and the heat pump, which may be configured as separate stand-alone units or integrated into a combined unit.

In some variations, the systems may be configured or operated so that the dispatchable electrical energy e2 generated from the hot reservoir is about equal to the electrical energy e1 generated by the photovoltaic-thermal solar energy collector. In some variations, the systems are configured or operated so that e2 is at least about 0.5 times e1, at least about 0.6 times e1, at least about 0.7 times el, at least about 0.8 times e1, or at least about 0.9 times e1. In some cases, e2 may be greater than e1.

Any of these systems may employ one or more heat transfer fluids for carrying heat. For example, systems may comprise a heat transfer fluid for carrying heat h1 generated by the photovoltaic-thermal solar energy collector and/or a heat transfer fluid for carrying heat h2 drawn from the cold reservoir. For example, in some variations, a system comprises a heat transfer fluid HTF1 that, in operation, flows through one or more fluid channels in the photovoltaic-thermal solar energy collector to collect heat h1. In some variations, a system comprises a heat transfer fluid HTF2 that carries heat h2 produced by the heat pump. In some variations, a system comprises a heat transfer fluid HTF1 for carrying heat h1 and a heat transfer fluid HTF2 for carrying heat h2.

During operation of some variations of the systems, a heat transfer fluid HTF1 heated by the photovoltaic-thermal solar energy collector and carrying heat h1 has a temperature T1 that is greater than a temperature T2 of the heat transfer fluid HTF2 heated by the heat pump and carrying h2. In some cases, a heat transfer fluid HTF1 carrying heat h1 has a temperature T1 that is less than a temperature T2 of a heat transfer fluid HTF2 carrying heat h2. In some cases, a temperature Ti of a heat transfer fluid HTF1 carrying heat h1 is approximately equal to a temperature T2 of a heat transfer fluid HTF2 carrying heat h2.

Optionally, any of the systems may employ one or more heat exchangers. For example, a system may comprise any one of or any combination of two or more of the following heat exchangers: a) a heat exchanger for transferring heat h1 from the photovoltaic-thermal solar energy collector to the hot reservoir; b) a heat exchanger for transferring heat h2 from the heat pump to the hot reservoir; and c) a heat exchanger for transferring heat between a heat transfer fluid HTF1 carrying heat h1 and a heat transfer fluid HTF2 carrying heat h2.

A variety of system configurations may be used for heating the hot reservoir with heat h1 and heat h2 using one or more heat transfer fluids. In one variation, a heat transfer fluid HTF1 flows through one or more fluid channels in the photovoltaic-thermal solar energy collector to collect heat h1. A heat transfer fluid HTF2 carries h2 from the heat pump. The heat transfer fluid HTF1 passes through a heat exchanger to transfer heat h1 to a heat transfer fluid HTF3. Heat transfer fluid HTF3 carrying heat h1 and heat transfer fluid HTF2 carrying h2 are used to heat the hot reservoir. For example, the heat transfer fluids HTF2 and HTF3 may be combined in the hot reservoir. Optionally, the heat transfer fluid HTF1 may be recirculated in a closed or open recirculation loop through one or more fluid channels in the photovoltaic-thermal solar energy collector and the heat exchanger.

In some variations of the systems, the photovoltaic-thermal solar energy collector is used to boost thermal energy of a heat transfer fluid carrying heat h2 from the heat pump. In one example, a heat transfer fluid HTF1 carrying heat h1 from the photovoltaic-thermal solar energy collector and having temperature T1 transfers thermal energy via a heat exchanger to a heat transfer fluid HTF2 carrying heat h2 from the heat pump having temperature T2 that is less than T1. Following heat exchange, the heat transfer fluid HTF2 carries heat h1+h2 (minus possible heat loss due to transfer inefficiency) that is used to heat the hot reservoir. Optionally, the heat transfer fluid HTF1 may be recirculated through one or more fluid channels in the photovoltaic-thermal solar energy collector in an open or closed recirculation loop. In another example, a heat transfer fluid HTF2 heated by the heat pump and carrying heat h2 flows through one or more fluid channels in the photovoltaic-thermal solar energy collector to collect additional heat h1. Following boosting by the photovoltaic-thermal solar energy collector, the heat transfer fluid HTF2 carries heat h2+h1 which is used to heat the hot reservoir.

In other variations of the systems, the heat pump is used to boost the thermal energy of a heat transfer fluid carrying heat h1 from the photovoltaic-thermal solar energy collector. In one example, a heat transfer fluid HTF2 carrying heat h2 from the heat pump and having temperature T2 transfers thermal energy via a heat exchanger to a heat transfer fluid HTF1 carrying heat h1 from the photovoltaic-thermal energy solar collector having temperature T1 that is less than T2. Following heat exchange, the heat transfer fluid HTF1 carries heat h1+h2 (minus possible heat loss due to transfer inefficiency) that is used to heat the hot reservoir. In another example, a heat pump draws heat h1 from a heat transfer fluid HTF1 that collects heat from the photovoltaic-thermal solar energy collector. The heat pump draws heat h2 from the cold reservoir. A heat transfer fluid HTF2 carrying h1+h2 from the heat pump is used to heat the hot reservoir.

Any suitable cold reservoir may be used in the systems. In some cases, at least a portion of the cold reservoir is the ambient environment. In some cases, the cold reservoir is the ambient environment. In some cases, the cold reservoir may be passively cooled by the ambient environment. In some cases, the cold reservoir may be actively cooled (e. g., using a portion of electrical energy e1 and/or an external cooling source). The negative heat (cold) in the cold reservoir may in some variations be allowed to dissipate to the environment, and in some variations the cold may be stored for use. For example, the cold reservoir may comprise a vessel containing a thermal storage medium (for example, water, ice, or a mixture of water and ice) from which heat may be drawn. The cooled thermal storage medium may be used for one or more cooling applications. In some cases, the cold reservoir from which heat is drawn may be used for cooling one or more applications internal to the system or external to the system. For example, the cold reservoir may be utilized for cooling the heat engine, e. g., a condensing portion of the heat engine. In certain variations in which the heat engine comprises an organic Rankine cycle engine, the cold reservoir may be used for cooling the organic Rankine cycle engine, e. g., a condensing portion of the organic Rankine cycle engine. In some systems, the cold reservoir may be used to cool one or more photovoltaic cells in a receiver in the photovoltaic-thermal solar energy collector.

The systems may employ a variety of schemes by which the heat pump is driven. The heat pump may be driven at least in part using electrical energy e1. In some cases, substantially all of the electrical energy e1 generated is used to drive the heat pump. In other cases, a portion of the generated electrical energy e1 is used to drive the heat pump, and a portion of e1 is used for another application that may be an internal application within the system or an external application outside of the system. In some situations, external energy e3 from an external energy source is used in combination with electrical energy e1 to drive the heat pump. External energy e3 may be from any type of supplemental energy source, including mechanical energy, energy derived from burning fossil fuels or plant-based fuels, or electrical energy (e. g., from the power grid, a generator, a battery, another solar energy collector, a wind turbine, a hydroelectric source, or the like). The energies e1 and e3 may be used in any suitable relative amounts and may be combined in any manner to drive the heat pump. For example, e1 and e3 may be used in a parallel operation so that both e1 and e3 are supplied simultaneously to the heat pump in any relative amounts. The relative amounts of e1 and e3 need not stay constant with time, and may be adjusted according to operating conditions (e. g., time of day, weather, season and/or demand). In other instances, e1 and e3 may be supplied in an alternating manner to the heat pump. The alternating scheme may be at regular intervals, or may be irregular intervals determined by an operator based on operating conditions. If e1 and e3 are alternated at regular intervals, the frequency at which they are alternated may be any suitable frequency and the frequency of alternating may be adjusted during operation to accommodation conditions, for example time of day, weather, season and/or demand. For example, e1 may be used during peak sunlight hours and e3 may be used during darkness. The duration of alternating intervals may be adjusted, for example, seasonally.

In these systems, at least a portion of heat h1 and at least a portion of heat h2 are used to heat the hot reservoir, but it is not required that heats hl and h2 be used continuously or simultaneously to heat the hot reservoir, and instead any combination of heat h1 and h2 may be applied intermittently, or heat h1 and heat h2 may be alternately used to heat the hot reservoir. In some variations, the systems employ an external heat source h3 to supply supplemental heat to the hot reservoir.

In these systems, the photovoltaic-thermal solar energy collector may be capable of generating any suitable relative quantities of heat h1 and electrical energy e1. For example, in some variations, heat h1 is approximately four times e1. The systems may be capable of heating a hot reservoir using heat h1 from the photovoltaic-thermal solar energy collector and heat h2 drawn from the cold reservoir by the heat pump so that the thermal energy in the hot reservoir is, for example, about 6 times e1, about 7 times e1, about 8 times e1, about 9 times e1 or about 10 times e1.

A system may be operated at any suitable operating temperature to achieve a desired temperature difference between the hot reservoir and the cold reservoir that is used by the heat engine to generate electrical energy e2. In some variations, the hot reservoir in operation may have a temperature T_{H} of about 100° C.-120° C. and the cold reservoir may have a temperature T_{C} of about 25° C.-40° C. A photovoltaic receiver in the photovoltaic-thermal solar energy collector in the system may utilize any suitable type of photovoltaic cells that demonstrates sufficient efficiency at the desired operating temperature. In some cases, one or more photovoltaic cells that are capable of demonstrating a desired efficiency at a temperature of about 100° C., about 120° C., or even higher are used. In some cases, one or more heterojunction intrinsic thin film photovoltaic cells may be used in the receiver.

One variation of a system for generating dispatchable electrical energy according to the first aspect of the invention comprises one or more concentrating photovoltaic-thermal solar energy collectors comprising a reflector for focusing incident solar radiation on a receiver. The receiver comprises one or more photovoltaic cells that generate electrical energy e1. The system comprises a cold reservoir and a heat pump driven at least in part by electrical energy e1 that draws heat h2 from the cold reservoir. The system comprises a hot reservoir that, in operation, is heated at least in part with heat h1 and h2. The system comprises an organic Rankine cycle engine that converts thermal energy in the hot reservoir to electrical energy e2 using the temperature difference between the hot and cold reservoirs. The system may be capable of generating electrical energy e2 that is at least about 0.5 times e1, at least about 0.6 times e1, at least about 0.7 times e1, at least about 0.8 times e1, at least about 0.9 times e1, about e1, or greater than e1. In some variations, the system may be configured for generating electrical energy e2 at a time delayed relative to the generation of electrical energy e1. In some variations, the system may be operated so that the hot reservoir is at temperature in a range from about 100° C. to 120° C. and the cold reservoir is at a temperature in a range from about 25° C. to about 40° C.

Methods for generating dispatchable useful work (e.g., dispatchable electric energy) according to a second aspect of the invention comprise generating electrical energy e1 and collecting heat h1 using a concentrating photovoltaic-thermal solar energy collector, drawing heat h2 from a cold reservoir using a heat pump optionally powered at least in part by electrical energy e1, heating a hot reservoir with heat h1 and heat h2, and generating electrical energy e2 from thermal energy in the hot reservoir. Electrical energy e2 is dispatchable energy that may be used as demanded, for example, during low solar output periods, or during high demand times.

In certain variations, the methods are used to generate electrical energy e2 at a time delayed relative to the generation of electrical energy e1, for example, a method may comprise storing thermal energy for a time period in the hot reservoir, and upon demand, converting the stored thermal energy to electrical energy e2. In some cases, a method may comprise generating electrical energy e2 from the hot reservoir while generating at least some electrical energy e1 using the photovoltaic-thermal solar energy collector. In some cases, a method may comprise generating electrical energy e2 from the hot reservoir during a time period in which no electrical energy e1 is being generated by the photovoltaic-thermal solar energy collector.

The methods may utilize any suitable means, apparatus, or scheme to convert thermal energy in the hot reservoir to electrical energy e2. In some cases, a method comprises using a heat engine to convert thermal energy of the hot reservoir to electrical energy e2. In some variations, the methods comprise operating the heat pump in a reverse direction so that heat flows from the hot reservoir to the cold reservoir to generate electrical energy e2. In some methods, an organic Rankine cycle engine is used to convert thermal energy in the hot reservoir to electrical energy e2. In some variations, an organic Rankine cycle engine is used in combination with the heat pump to convert thermal energy in the hot reservoir to electrical energy e2.

The methods may be adapted for generating any suitable quantity of dispatchable electrical energy e2 relative to a quantity of electrical energy e1 generated by the photovoltaic-thermal energy solar collector. For example, the methods may be adapted for generating dispatchable electrical energy e2 that is at least about 0.5 times e1, at least about 0.6 times e1, at least about 0.7 times e1, at least about 0.8 times e1, at least about 0.9 times e1, or about equal to e1. In some cases, the methods may be adapted to generate e2 that is greater than e1.

In any of these methods, one or more heat transfer fluids may be used for transferring heat h1 generated by the photovoltaic-thermal solar energy collector and/or heat h2 drawn from the cold reservoir to the hot reservoir. For example, in some variations, a heat transfer fluid HTF1 may be flowed through one or more fluid channels in the photovoltaic-thermal solar energy collector to collect heat h1. In some methods, a heat transfer fluid HTF2 may be heated by the heat pump to carry h2. In some methods, a heat transfer fluid HTF1 may be flowed through one or more fluid channels in the photovoltaic-thermal solar energy collector to collect heat h1 and a heat transfer fluid HTF2 may be heated by the heat pump to carry heat h2.

Optionally, any of these methods may employ one or more heat exchangers. For example, a method may use any one of or any combination of two or more of the following heat exchangers: a) a heat exchanger for transferring heat h1 from the photovoltaic-thermal solar energy collector to the hot reservoir; b) a heat exchanger for transferring heat h2 from the heat pump to the hot reservoir; and c) a heat exchanger for transferring heat between a heat transfer fluid HTF1 carrying heat h1 and a heat transfer fluid HTF2 carrying heat h2.

In some variations of the methods, a heat transfer fluid HTF1 heated by the photovoltaic-thermal solar energy collector and carrying heat h1 has a temperature T1 that is greater than a temperature T2 of the heat transfer fluid HTF2 heated by the heat pump and carrying heat h2. In other variations of the methods, a heat transfer fluid HTF1 carrying heat h1 has temperature T1 that is less than temperature T2 of a heat transfer fluid HTF2 carrying h2. In still other variations of the methods, a heat transfer fluid HTF1 carrying heat h1 has temperature Ti that is approximately equal to temperature T2 of a heat transfer fluid HTF2 carrying h2.

Several variations of the methods may be employed for heating the hot reservoir with heat h1 and heat h2 using one or more heat transfer fluids. In one variation, the methods comprise flowing a heat transfer fluid HTF1 through one or more fluid channels in the photovoltaic-thermal solar energy collector to collect heat h1, and collecting heat h2 from the heat pump with a heat transfer fluid HTF2. The methods may comprise passing the heat transfer fluid HTF1 through a heat exchanger to transfer heat h1 to a heat transfer fluid HTF3, and using the heat transfer fluid HTF3 carrying h1 and the heat transfer fluid HTF2 carrying heat h2 to heat the hot reservoir. In some variations, the heat transfer fluids HTF2 and HTF3 may be combined in the hot reservoir. Optionally, the methods may comprising recirculating the heat transfer fluid HTF1 in a closed or open recirculation loop through one or more fluid channels in the photovoltaic-thermal solar energy collector and the heat exchanger.

In some variations of the methods, the photovoltaic-thermal solar energy collector is used to boost thermal energy of a heat transfer fluid carrying heat h2 from the heat pump. In one example, the methods comprise transferring heat via a heat exchanger from a heat transfer fluid HTF1 carrying heat h1 from the photovoltaic-thermal solar energy collector and having temperature T1 to a heat transfer fluid HTF2 carrying heat h2 from the heat pump having temperature T2 that is less than T1. Following heat exchange, the methods comprise using the heat transfer fluid HTF2 carrying heat h1+h2 (minus possible heat loss due to transfer inefficiency) to heat the hot reservoir. Optionally, the methods comprise recirculating the heat transfer fluid HTF2 through one or more fluid channels in the photovoltaic-thermal solar energy collector and the heat exchanger in an open or closed recirculation loop. In another example, the methods comprise passing a heat transfer fluid HTF2 carrying heat h2 from the heat pump through one or more fluid channels in the photovoltaic-thermal solar energy collector to collect additional heat h1. Following boosting by the photovoltaic-thermal solar energy collector, the methods comprise using the heat transfer fluid HTF2 carrying heat h2+h1 to heat the hot reservoir.

In other variations of the methods, the heat pump is used to boost the thermal energy of a heat transfer fluid carrying heat h1 from the photovoltaic-thermal solar energy collector. In one example, the methods comprise transferring heat a via heat exchanger from a heat transfer fluid HTF2 carrying heat h2 from the heat pump and having temperature T2 to a heat transfer fluid HTF1 carrying heat h1 and having temperature T1 that is less than T2. Following heat exchange, the methods comprise using the heat transfer fluid HTF1 carrying heat h1+h2 (minus possible heat loss due to transfer inefficiency) to heat the hot reservoir. In another example, the methods comprise using the heat pump to draw heat h2 from the cold reservoir and to draw heat h1 from a heat transfer fluid HTF1 that collects heat from the photovoltaic-thermal solar energy collector. The methods comprise using a heat transfer fluid HTF2 carrying heat h1+h2 from the heat pump to heat the hot reservoir.

Any suitable cold reservoir may be used in the methods. Some methods use the ambient environment as at least a portion of the cold reservoir. Some methods use the ambient environment as the cold reservoir. In some methods, the cold reservoir may be actively cooled (e. g., using an external energy source and/or using a portion of electrical energy e1 generated by the photovoltaic-thermal energy solar collector) or may be passively cooled using the ambient environment. Some methods use a vessel containing a thermal storage medium (for example, water, ice, or a mixture of water and ice) as the cold reservoir from which heat may be drawn by the heat pump.

Negative heat (cold) in the cold reservoir may or may not be stored for use. In some cases, the cooling is not stored, and is allowed to dissipate into the environment. In other cases, the methods may comprise storing a cooled thermal energy storage medium (e.g., water, ice, or a mixture of water and ice) in the cold reservoir for use. Some variations of the methods may use the cold reservoir for a cooling application in a photovoltaic-thermal energy solar collector, heat pump, heat engine, or other system components used in the methods. For example, certain methods may comprise using the cold reservoir for cooling a heat engine, e. g., a condensing portion of the heat engine, that is used to convert thermal energy in the hot reservoir to electrical energy e2. In those variations in which an organic Rankine cycle engine is used to convert thermal energy in the hot reservoir to electrical energy e2, the methods may comprise using the cold reservoir for cooling a condensing portion of the organic Rankine cycle engine. Some methods may comprise cooling one or more photovoltaic cells in a receiver in the photovoltaic-thermal solar energy collector using the cold reservoir. Certain method may comprise using the cold reservoir to cool a heat engine and cooling one or more photovoltaic cells. Variations of the methods comprise using the cold reservoir to cool an application external to the photovoltaic-thermal solar energy collector, heat pump, heat engine, and associated components.

The methods may employ a variety of schemes by which the heat pump is driven. The heat pump may be driven at least in part using electrical energy e1. Some methods comprise using substantially all of the electrical energy e1 generated to drive the heat pump.

Other methods comprise using a portion of the generated electrical energy e1 to drive the heat pump, and using a portion of e1 for one or more additional applications. Certain variations of the methods comprise using external energy e3 from an external energy source and electrical energy e1 to drive the heat pump. External energy e3 may be from any type of supplemental energy source, including mechanical energy, energy derived from burning fossil fuels or plant-based fuels, or electrical energy (e. g., from the power grid, a generator, a battery, another solar energy collector, a wind turbine, a hydroelectric source, or the like). The energies e1 and e3 may be used in any suitable relative amounts and may be combined in any manner to drive the heat pump. For example, in some methods, e1 and e3 are used in a parallel operation so that both e1 and e2 are supplied simultaneously to the heat pump in any relative amounts. The relative amounts of e1 and e2 need not stay constant with time, and may be adjusted according to operation conditions (e. g., time of day, weather, season and/or demand). In other variations of the methods, e1 and e3 are supplied in an alternating manner to the heat pump. The alternating scheme may be at regular intervals, or may be at irregular intervals determined by an operator based on operating conditions. If e1 and e3 are alternated at regular intervals, the frequency at which they are alternated may be any suitable frequency and the frequency of alternating may be adjusted during operation to accommodate conditions, for example time of day, weather, season and/or demand. For example, e1 may be used during peak sunlight hours and e3 may be used during darkness. The duration of alternating intervals may be adjusted, for example, seasonally.

In these methods, at least a portion of heat h1 and at least a portion of heat h2 are used to heat the hot reservoir, but it is not required that heats h1 and h2 be used continuously or simultaneously to heat the hot reservoir, and instead any combination of heat h1 and h2 may be applied intermittently, or heat h1 and heat h2 may be alternately used to heat the hot reservoir. Some variations of the methods may comprise using a supplemental heat source h3 to heat the hot reservoir.

These methods may be adapted for generating any suitable relative quantities of heat h1 and electrical energy e1 using the photovoltaic-thermal solar energy collector. For example, the methods may produce heat h1 that is approximately e1, about 2 times e1, about 3 times e1, about 4 times e1, about 5 times e1, about 6 times e1, about 7 times e1, about 8 times e1, about 9 times e1, or 10 times e1. In some cases, the methods produce h1 that is about 4 times e1. The methods may be adapted for heating the hot reservoir using heat h1 from the photovoltaic-thermal solar energy collector and heat h2 drawn by the heat pump from the cold reservoir so that the thermal energy in the hot reservoir is about e1, about 2 times e1, about 3 times e1, about 4 times e1, about 5 times e1, about 6 times e1, about 7 times e1, about 8 times e1, about 9 times e1 or about 10 times e1.

In these methods, the receiver in the photovoltaic-thermal solar energy collector may operate at any suitable temperature. In some cases, the methods include operating a photovoltaic portion of the receiver at temperatures of about 100° C.-120° C. Photovoltaic cells may be selected to have optimal efficiencies over the desired operating temperature range. For example, in methods in which the receiver is operated at a temperature of about 110° C.-120° C., one or more heterojunction intrinsic thin film photovoltaic cells may be used in the receiver.

Solar energy systems according to a third aspect of the invention comprise a concentrating photovoltaic-thermal solar energy collector capable of generating electrical energy Wₑ and collecting heat Q₁ for use in one or more applications. The systems comprise a cold reservoir and a hot reservoir that is configured to be heated at least in part using solar-generated heat Q₁. The systems comprise a heat pump that may be configured to be powered at least in part using solar-generated electrical energy Wₑ. The heat pump (e.g., a chiller) is configured to draw heat from the cold reservoir, thereby reducing a temperature of the cold reservoir. The heat pump may exhaust the heat drawn from the cold reservoir to the ambient environment, for example. The systems comprise a heat engine that is configured to operate between the hot reservoir and the cold reservoir to generate useful work. In some variations, the heat engine is configured to generate electrical work.

The solar energy systems may be configured for storing energy in the hot and cold reservoirs and operating the heat engine at a time delayed relative to the generation of electrical energy Wₑ to generate dispatchable useful work, e. g., dispatchable electrical energy. The dispatchable useful work may be produced as demanded, for example, during low solar output times, or during high demand periods. In some variations, the systems may be configured for generating an amount of dispatchable electrical energy that is at least 0.5 times the solar-generated electrical energy Wₑ, at least 0.6 times Wₑ, at least 0.7 times Wₑ, at least 0.8 times Wₑ, or at least 0.9 times Wₑ. In some cases, the systems may be configured for generating an amount of dispatchable electrical energy that is about equal to the solar-generated electrical energy Wₑ. Some systems are configured for generating an amount of dispatchable electrical energy that is greater than the solar-generated electrical energy Wₑ.

The heat pump or chiller used in these systems may be any suitable type of heat pump or chiller. Non-limiting examples include vapor-compression chillers, absorption chillers, and adsorption chillers.

The heat engine used in the systems may be any suitable type of heat engine. Non-limiting examples include organic Rankine cycle heat engines, Stirling heat engines, Brayton cycle heat engines, and thermoelectric devices. In some variations, the heat engine comprises an organic Rankine cycle heat engine.

In some variations of the systems, the heat pump and the heat engine may share one or more common components. In some cases, the heat engine comprises the heat pump operated in a reverse direction. In certain variations of the systems, the heat pump and the heat engine may be integrated into a combined unit.

Certain variations of the systems comprise a controller configured for controlling during operation a portion of solar-generated electrical energy Wₑ that is used to power the heat pump and a portion of electrical energy Wₑ that is supplied to an electrical grid based on a time-dependent market value of electricity.

Although the heat pump in these systems may be configured to be powered at least in part using solar-generated electrical energy Wₑ, at certain times during operation the heat pump may be powered in part or completely by an external energy source e₃ (e.g., an electrical power grid). At various times during operation, the heat pump may be powered by any one of: a) electrical energy Wₑ; b) external energy source e₃; c) electrical energy Wₑ alternated with external energy source e₃; and d) electrical energy Wₑ in parallel with external energy source e₃. In some operational modes, substantially all of electrical energy Wₑ is used to drive the heat pump. In other modes, a portion of Wₑ is used for another application that may be an internal application within the system, or an eternal application outside the system (e.g., a portion of Wₑ may be delivered to the grid). If external energy source e₃ is used to drive the heat pump, external energy e₃ may be from any type of supplemental energy source, including the power grid, a generator, a battery, another solar energy collector, a wind turbine, a hydroelectric source, mechanical energy, energy derived from burning fossil fuels or plant-based fuels, and the like. If external energy e₃ is used in combination with all or a portion of Wₑ to drive the heat pump, any suitable relative amounts of Wₑ and e₃ may be used, and Wₑ and e₃ may be combined in any manner to drive the heat pump.

In these systems, at least a portion of solar-generated heat Q₁ is used to heat the hot reservoir, but it is not required that all of heat Q₁ be used to heat the hot reservoir. In some variations, substantially all of heat Q₁ is used to heat the hot reservoir, and in other variations, a portion of heat Q₁ is diverted for a use other than heating the hot reservoir. In some variations, the systems may employ a supplemental heat source to heat the hot reservoir.

The systems comprise a photovoltaic-thermal solar energy collector configured for providing any suitable ratio of heat Q₁ to electrical energy Wₑ. In some cases, the ratio Q₁:Wₑ is in a range from about 3 to about 6, or in a range from about 3 to about 5. In some cases, the ratio Q₁:Wₑ is about 3. In some cases, the ratio Q₁:Wₑ is about 4. In some cases, the ratio Q₁:Wₑ is about 5.

The photovoltaic-thermal solar energy collector in the systems may be operated at any suitable temperature. In some cases, the photovoltaic-thermal solar energy collector operates at a temperature of about 100° C.-120° C., or about 110° C.-120 ° C. In those cases, photovoltaic cells may be selected that have useful efficiencies at an operating temperature of about 120° C. For example, the photovoltaic-thermal solar energy collector may comprise one or more heterojunction intrinsic thin film photovoltaic cells capable of generating electrical energy at an operating temperature of about 120° C.

A system may be operated to achieve a desired temperature difference between the hot reservoir and the cold reservoir so that the heat engine operating between the hot and cold reservoir operates with a desired efficiency. For example, if the heat engine is an organic Rankine cycle heat engine, the hot reservoir may be operated at about 110° C.-120° C. (e.g., about 110° C., about 115° C., or about 120° C.) and the cold reservoir may be cooled to a temperature of about −5° C. to about 10° C., e.g., about −5° C., about −3° C., about 0° C., about 1° C., about 2° C., about 3° C., about 5° C., about 6° C., about 7° C., about 8° C., about 9° C., or about 10° C. In some cases, the heat engine is an organic Rankine cycle heat engine and the hot reservoir is operated at about 120° C. and the cold reservoir is cooled to a temperature in a range from about 0° C. to about 7° C., e.g., about 0° C., about 1° C., about 2° C., about 3° C., about 5° C., about 6° C., or about 7° C.

One variation of a system according to the third aspect of the invention comprises one or more concentrating photovoltaic-thermal solar energy collectors, each comprising one or more reflectors for focusing incident solar radiation on a receiver. The receiver comprises one or more photovoltaic cells that generate electrical energy Wₑ, and one or more fluid channels through which a heat transfer fluid flows and collects heat Q₁ produced in the receiver. The system comprises a cold reservoir and a hot reservoir. The system comprises a chiller configured to draw heat from the cold reservoir, thereby lowering a temperature of the cold reservoir, and an organic Rankine cycle heat engine configured to operate between the hot reservoir and the cold reservoir to generate useful work. The chiller may be configured to be driven at least in part by electrical energy Wₑ. In some variations of the system, the organic Rankine cycle heat engine is configured for generating electric work. The system may be configured for operating the heat engine to generate useful work at a time delayed relative to the generation of electrical energy Wₑ, so that energy is effectively stored in the hot and cold reservoirs.

Methods for generating dispatchable useful work (e.g., dispatchable electrical energy) according to a fourth aspect of the invention comprise generating electrical energy Wₑ and collecting heat Q₁ using a concentrating photovoltaic-thermal solar energy collector, drawing heat from a cold reservoir to reduce a temperature of the cold reservoir, heating a hot reservoir at least in part using heat Q₁, and operating a heat engine between the hot reservoir and the cold reservoir to generate useful work, e.g., electrical work. The heat drawn from the cold reservoir may be exhausted to the ambient environment, for example. In certain variations, the methods comprise powering a heat pump at least in part using electrical energy Wₑ to draw heat from the cold reservoir.

In certain variations, the methods are used to generate dispatchable useful work at a time delayed relative to the generation of electrical energy Wₑ. For example, a method may comprise storing energy for a time period in the hot and cold reservoirs, and upon demand, operating the heat engine to convert the stored energy in the hot and cold reservoirs to generate useful work (e.g., electrical work). The dispatchable energy may be produced upon demand, for example, during low solar output periods or during high power demand periods. In some cases, the methods comprise generating an amount of dispatchable electric energy that is at least about 0.5 times Wₑ, at least about 0.6 times Wₑ, at least about 0.7 times Wₑ, at least about 0.8 times Wₑ, or at least about 0.9 times Wₑ. In certain cases, the methods comprise generating an amount of dispatchable electric energy that is approximately equal to Wₑ. In some cases, the methods comprise generating an amount of dispatchable electric energy that is greater than Wₑ.

The methods may employ any suitable type of heat pump or chiller for drawing heat from the cold reservoir to reduce the temperature of the cold reservoir. Non-limiting examples include vapor-compression chillers, absorption chillers, and adsorption chillers.

The methods may employ any suitable type of heat engine to operate between the hot reservoir and the cold reservoir to generate useful work. Non-limiting examples include organic Rankine cycle heat engines, Stirling heat engines, Brayton heat engines, and thermoelectric devices. In some variations, the heat engine comprises an organic Rankine cycle heat engine.

At certain times during operation the methods may employ an external energy source e₃ (e.g., an electric power grid) to drive the heat pump. At other times during operation, the methods may comprise driving the heat pump solely using solar-generated Wₑ. In some modes of operation, the methods may comprise using Wₑ in combination with an external energy source e₃ to drive the heat pump, where Wₑ and e₃ may be delivered in parallel or in an alternating scheme. If external energy source e₃ is used to drive the heat pump, external energy e₃ may be from any type of supplemental energy source, including the power grid, a generator, a battery, another solar energy collector, a wind turbine, a hydroelectric source, mechanical energy, energy derived from burning fossil fuels or plant-based fuels, and the like. If external energy e₃ is used in combination with all or a portion of Wₑ to drive the heat pump, any suitable relative amounts of Wₑ and e₃ may be used, and Wₑ and e₃ may be combined in any manner to drive the heat pump.

In these methods, at least a portion of solar-generated heat Q₁ is used to heat the hot reservoir, but it is not required that all of heat Q₁ be used to heat the hot reservoir. In some variations, substantially all of heat Q₁ is used to heat the hot reservoir, and in other variations, a portion of heat Q₁ is diverted for a use other than heating the hot reservoir. In some variations, the methods may employ a supplemental heat source to heat the hot reservoir.

In some operational modes, the methods comprise using substantially all of electrical energy Wₑ to drive the heat pump. In other operational modes, the methods may divert essentially all or a portion of Wₑ for another application that may be an internal application within the system, or an external application outside the system. At certain times during operation, essentially all of Wₑ, or a portion of Wₑ (e.g., the balance of Wₑ that is not used to drive the heat pump) may be supplied to the grid. The methods may comprise controlling the portion of electrical energy Wₑ that is used to power the heat pump and the portion of electrical energy Wₑ that is supplied to the power grid based on a time-dependent market value of electric energy.

The methods may comprise operating the photovoltaic-thermal solar energy collector at any suitable temperature. In some cases, the photovoltaic-thermal solar energy collector is operated at a temperature of about 100° C.-120° C., or about 110° C.-120° C. In those cases, photovoltaic cells in the photovoltaic-thermal solar energy collector may be selected that have useful efficiencies at an operating temperature of about 120° C. For example, the photovoltaic-thermal solar energy collector may comprise one or more heterojunction intrinsic thin film photovoltaic cells capable of generating electrical energy at an operating temperature of about 120° C.

The methods may comprise heating the hot reservoir and cooling the cold reservoir to achieve a desired temperature difference between the hot reservoir and the cold reservoir so that the heat engine operating between the hot and cold reservoir operates with a desired efficiency. The methods may comprise reducing the temperature of the cold reservoir to a temperature T_{L}, where T_{L} is selected to optimize energy stored in the hot and cold reservoirs from which dispatchable energy is produced by operation of the heat engine. In certain methods utilizing an organic Rankine cycle heat engine, the methods may comprise heating the hot reservoir to a temperature of about 110° C.-120° C. (e.g., about 110° C., about 115° C., or about 120° C.) and cooling the cold reservoir to a temperature of about −5° C. to about 10° C., e.g., about −5° C., about −3° C., about −2° C., about −1° C., about 0° C., about 1° C., about 2° C., about 3° C., about 5° C., about 6° C., about 7° C., about 8° C., about 9° C., or about 10° C. Some methods employing an organic Rankine cycle heat engine comprise storing water in the hot reservoir at a temperature of about 120° C. and cooling water in the cold reservoir to a temperature T_{L} that is in a range from about −5° C. to about 10° C., or from about −3° C. to about 7° C., or from about 0° C. to about 7° C., or from about 0° C. to about 5° C. For example the temperature of the hot reservoir may be about 120° C. and T_{L} may be about −3° C., about −2° C., about −1° C., about 0° C., about 1° C., about 2° C., about 3° C., about 4° C., about 5° C., about 6° C., or about 7° C.

In certain modes of operation, the methods comprise alternating operation of the heat pump with operation of the heat engine, so that the heat pump and the heat engine are not operated at the same time.

The methods comprise generating electric energy Wₑ and collecting heat Q₁ using a photovoltaic-thermal solar energy collector, where a ratio of Q₁:Wₑ may be any suitable amount. For example, in some cases, the photovoltaic-thermal solar energy collector produces a ratio Q₁: Wₑ in a range from about 3 to about 6, or in a range from about 3 to about 5. In some cases, the ratio Q₁:Wₑ is about 3. In some cases, the ratio Q₁:Wₑ is about 4. In some cases, the ratio Q₁:Wₑ is about 5.

One variation of a method according to the fourth aspect of the invention comprises generating electrical energy Wₑ and collecting heat Q₁ using a concentrating photovoltaic-thermal solar energy collector, drawing heat from a cold reservoir to reduce a temperature of the cold reservoir using a chiller, heating a hot reservoir at least in part using heat Q₁, and operating an organic Rankine cycle heat engine between the hot reservoir and the cold reservoir to generate useful work, for example, electrical work. The chiller may be powered at least in part using Wₑ. The method may comprise effectively storing energy in the hot and cold reservoirs and operating the heat engine to generate useful work at a time delayed relative to the generation of electrical work Wₑ.

In the systems and methods summarized above for the first, second, third, and fourth aspects of the invention, all, some, or none of the electricity generated by the solar energy collector may be used to drive the heat pump (e.g., chiller), and the heat pump may additionally or alternatively be driven by, for example, electricity supplied from an external grid. In one mode of operation, for example, during daytime hours all or substantially all of the electricity generated by the solar energy collector is supplied to an external use such as, for example, an external commercial electric power grid. During evening hours, the heat engine (e.g., ORC) runs off stored heat to generate electricity that is also supplied to an external use. In late evening to early morning hours the heat pump (e.g., chiller) is driven with electricity drawn from an external commercial electric power grid. In this scheme the system supplies electricity to an external use during periods corresponding to peak demand and/or high electricity prices, and draws electricity from the external grid during periods in which electricity prices are typically lower and in which low ambient temperatures make operation of the heat pump more efficient.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 provides a flow chart describing a method for generating dispatchable electrical energy using a photovoltaic-thermal solar energy collector (PVT).

FIG. 2 illustrates one variation of a system comprising a photovoltaic-thermal solar energy collector (PVT) configured for generating electrical energy (e1) and heat energy (h1), and using at least a portion of the solar generated electrical energy e1 to drive a heat pump (HP) to draw heat h2 from a cold reservoir. Heat h2 and heat h1 are used to heat a hot reservoir. A heat engine (HE) is used to convert thermal energy in the hot reservoir to electrical energy e2 using a temperature difference between the hot reservoir and the cold reservoir.

FIG. 3 illustrates another variation of a system comprising a photovoltaic-thermal solar energy collector (PVT) configured for generating electrical energy (e1) and heat energy (h1), and using at least a portion of the solar generated electrical energy e1 to drive a heat pump to draw heat h2 from a cold reservoir. Heat h2 and heat h1 are used to heat a hot reservoir. In this particular example, the heat pump operating in a reversed manner is used to convert thermal energy in the hot reservoir to electrical energy e2 using a temperature difference between the hot reservoir and the cold reservoir.

FIGS. 4A-4E illustrate various non-limiting examples of schemes to use heat h1 generated by a photovoltaic-thermal solar energy collector and heat h2 drawn from the cold reservoir by the heat pump to heat the hot reservoir. In the example shown in FIG. 4A, a heat transfer fluid carrying heat h1 is mixed with a heat transfer fluid carrying heat h2. In the example shown in FIG. 4B, a heat transfer fluid carrying heat h2 passes through the PVT to boost its thermal energy. In the example shown in FIG. 4C, a heat transfer fluid carrying heat h1 transfers heat to a heat transfer fluid carrying h2 via heat exchange. In the example shown in FIG. 4D, a heat transfer fluid carrying heat h2 transfers heat to a heat transfer fluid carrying h1 via heat exchange. In the example shown in FIG. 4E, a heat pump is used to boost the thermal energy of a heat transfer fluid carrying heat h1.

FIG. 5A provides a schematic diagram of a solar energy system capable of delivering varying amounts of dispatchable electrical energy e2.

FIG. 5B provides a specific example of the of the solar energy system of FIG. 5A.

FIG. 6 illustrates a non-limiting example of a solar energy system comprising a photovoltaic-thermal solar energy collector that generates dispatchable electrical energy that may be used to deliver electrical power as demanded, for example, during periods of low sunlight or high demand.

FIGS. 7A and 7B illustrate mass (i.e., coolant) flow in two variations of systems, similar to those depicted in FIGS. 2-6.

FIG. 8A provides a schematic heat flow diagram for a variation of another solar energy collector system.

FIG. 8B provides a mass flow diagram for the solar energy collector system illustrated in FIG. 8A.

FIG. 9A provides a schematic heat flow diagram for another variation of a solar energy collector system.

FIG. 9B provides a mass flow diagram for the solar energy collector system illustrated in FIG. 9A.

FIG. 10 provides a schematic heat flow diagram for yet another variation of a solar energy collector system.

FIG. 11 provides a more detailed mass flow diagram for a variation of the solar energy collector system illustrated in FIG. 3.

FIG. 12 provides a non-limiting example of a solar energy system comprising a photovoltaic-thermal solar energy collector that collects heat Q₁ and electrical energy Wₑ that is configured for storing energy in hot and cold reservoirs, and using a heat engine operating between the hot and cold reservoirs to generate dispatchable useful work, whether or not solar radiation is available.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention. This description will clearly enable one skilled in the art to make and use the invention, and describes several embodiments, adaptations, variations, alternatives and uses of the invention, including what is presently believed to be the best mode of carrying out the invention. As used in this specification and the appended claims, the singular forms “a,” “an,” and “the” include plural referents unless the context clearly indicates otherwise.

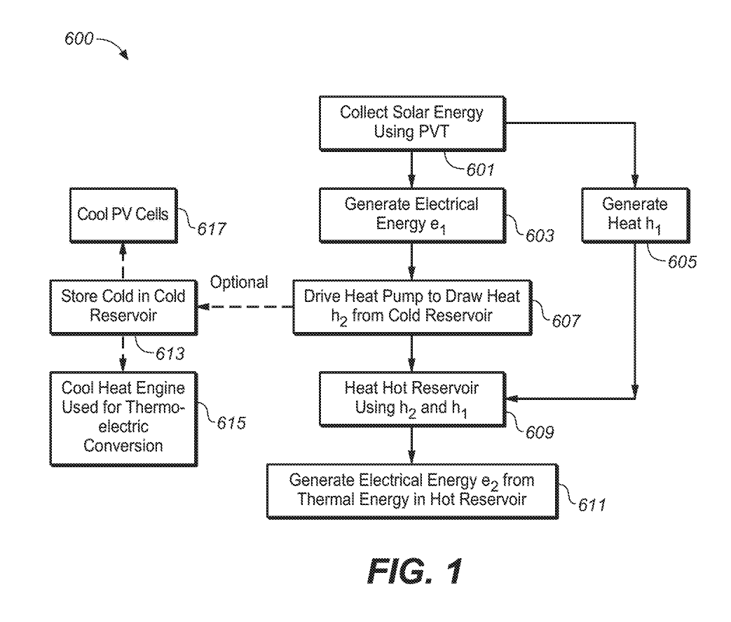

Described herein with reference to FIGS. 1-7B are solar energy systems, apparatus and methods comprising or utilizing one or more concentrating photovoltaic-thermal solar energy collectors to generate electrical energy e1 and heat h1. The methods comprise generating electrical energy e1 and collecting heat h1 using a concentrating photovoltaic-thermal solar energy collector, drawing heat h2 from a cold reservoir using a heat pump that may be driven at least in part by electrical energy e1, heating a hot reservoir with heat h1 and heat h2, and generating electrical energy e2 from thermal energy in the hot reservoir. The solar energy systems comprise a concentrating photovoltaic-thermal solar energy collector capable of generating electrical energy e1 and heat h1 for use in one or more applications. At least a portion of the solar-generated electrical energy e1 may be used to drive a heat pump to draw heat h2 from a cold reservoir. A hot reservoir is heated at least in part using at least a portion of heat h1 from the photovoltaic-thermal solar energy collector and at least a portion of heat h2 generated by the heat pump. Electrical energy e2 produced by the systems and methods is dispatchable energy and may be used as demanded, for example, during low solar output periods or during increased demand. The systems and methods may be capable of generating dispatchable electrical energy e2 that is at least about 0.5 times e1, at least about 0.6 times e1, at least about 0.7 times e1, at least about 0.8 times e1, at least about 0.9 times e1, about equal to e1, or greater than e1.

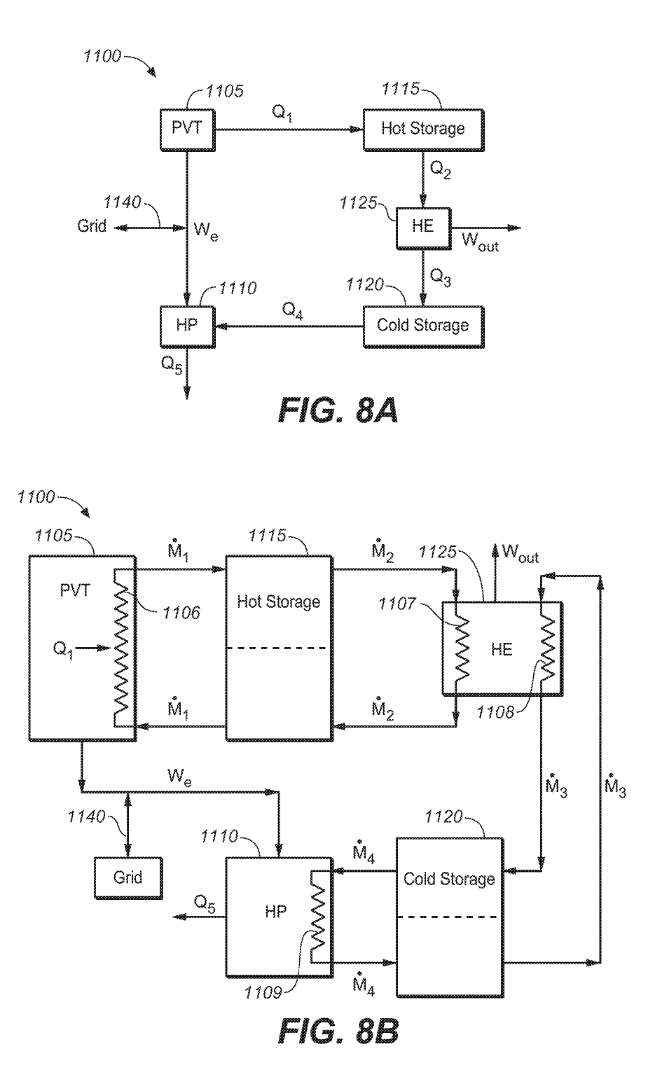

Described herein with reference to FIGS. 8A-12 are additional solar energy systems, apparatus and methods comprising or utilizing one or more concentrating photovoltaic-thermal solar energy collectors to generate electrical energy and collect heat. The methods comprise generating electrical energy Wₑ and collecting heat Q₁ using a concentrating photovoltaic-thermal solar energy collector, drawing heat from a cold reservoir using a heat pump, thereby lowering the temperature of the cold reservoir, heating a hot reservoir at least in part using heat Q₁, and operating a heat engine between the hot and cold reservoirs to generate useful work (e.g., useful electrical work). The methods may utilize at least a portion of solar-generated electrical energy Wₑ to drive the heat pump. The methods may comprise storing energy in the hot and cold reservoirs and operating the heat engine at a time delayed relative to the generation of Wₑ to generate useful work. The heat engine may be operated whether or not solar radiation is available, so that the methods provide dispatchable energy that may be generated upon demand. The solar energy systems comprise one or more concentrating photovoltaic-thermal solar energy collectors capable of generating electrical energy Wₑ and collecting heat Q₁. The systems comprise a hot reservoir and a cold reservoir. During operation of the systems, at least a portion of heat Q₁ is used to heat the hot reservoir, and at least a portion of electrical energy Wₑ may be used to drive a heat pump to draw heat from the cold reservoir, thereby lowering the temperature of the cold reservoir. The systems comprise a heat engine that is configured to operate between the hot and cold reservoirs to generate useful work (e.g., electrical work). The systems may be configured so that the heat engine is configured to operate and generate useful work at a time delayed relative to the generation of electrical energy Wₑ, so that energy is effectively stored in the hot and cold reservoirs. The heat engine is capable of generating useful work whether or not solar radiation is available, so that dispatchable energy may be delivered upon demand.

The systems, methods and apparatus described herein comprise or use one or more photovoltaic-thermal solar energy collectors. A photovoltaic-thermal solar energy collector collects solar energy from which it generates electricity and also collects useful heat. A concentrating photovoltaic-thermal solar energy collector uses reflectors or other optics to concentrate solar energy onto one or more solar energy receivers. A receiver comprises one or more photovoltaic cells for generating electricity and one or more fluid channels through which a heat transfer fluid flows to collect heat. The electricity generating and heat collecting portions of the photovoltaic-thermal solar energy collector may be integrated with each other in some variations, or separated from each other in other variations. A concentrating photovoltaic-thermal solar energy collector may comprise, for example, a photovoltaic-thermal receiver and a solar thermal booster receiver arranged in series, where a heat transfer fluid is first used to actively cool and collect heat from the photovoltaic-thermal receiver, and the heat transfer fluid is subsequently passed through the solar thermal booster receiver to further increase the temperature of the heat transfer fluid. In such a scheme, the solar thermal booster receiver may lack any solar cells. Non-limiting examples of configurations of suitable photovoltaic-thermal solar energy collectors that may be used with the systems, apparatus and methods described herein include trough collectors, dish collectors, linear Fresnel collectors, heliostat collectors, and central tower collectors.

Certain photovoltaic cells may be selected for use in a receiver of a photovoltaic-thermal solar energy collector that permit useful operation at temperatures as high as 120° C. For example, heterojunction with intrinsic thin layer (HIT) silicon solar cells, which may, for example, be obtained from Sanyo Corp., may be operated with usable efficiency at 120° C. Additional non-limiting examples of photovoltaic solar cells that may be used in the systems and methods described herein include high efficiency solar cells manufactured by Silevo (Fremont, Calif.), Gallium Arsenide thin film photovoltaic cells (e.g., those manufactured by Alta Devices, Sunnyvale, Calif.), and multijunction (e.g., III-V material system) photovoltaic cells.

Non-limiting examples of suitable photovoltaic-thermal solar energy collectors that may be employed with the systems, apparatus and methods disclosed herein are described in the following publications: U.S. patent application Ser. No. 12/712,122 filed Feb. 24, 2010 and entitled “Designs for 1-D Concentrated Photovoltaic Systems”; U.S. patent application Ser. No. 12/788,048 filed May 26, 2010 and entitled “Concentrating Solar Photovoltaic-Thermal System”; U.S. patent application Ser. No. 12/622,416 filed Nov. 19, 2009 and entitled “Receiver for Concentrating Solar Photovoltaic-Thermal System”; U.S. patent application Ser. No. 12/774,436 filed May 5, 2010 and entitled “Receiver for Concentrating Solar photovoltaic-thermal System”; U.S. patent application Ser. No. 12/781,706 filed May 17, 2010 and entitled “Concentrating Solar Energy Collector”; U.S. patent application Ser. No. 13/079,193 filed Apr. 4, 2011 and entitled “Concentrating Solar Energy Collector”; U.S. patent application Ser. No. 13/291,531 filed Nov. 8, 2011 and entitled “Photovoltaic-Thermal Solar Energy Collector with Integrated Balance of System; U.S. patent application Ser. No. 13/371,790 filed Feb. 13, 2012 and entitled “Solar Cell with Metallization Compensating for or Preventing Cracking”; U.S. patent application Ser. No. 13/590,525 filed Aug. 21, 2012 and entitled “Maximizing Value form a Concentrating Solar Energy System”; and U.S. patent application Ser. No. 13/837,604 filed Mar. 15, 2013 and entitled “Concentrating Solar Energy Collector”, each of which is incorporated by reference herein in its entirety.

A photovoltaic-thermal solar energy collector system may comprise components other than a photovoltaic-thermal solar energy collector, such as one or more inverters to convert DC electricity generated by photovoltaic cells in the photovoltaic-thermal solar energy collector to alternating current, one or more heat transfer fluid control systems that circulate heat transfer fluid through the solar energy collector to collect heat, and, optionally, a control system that electrically and/or physically integrates the one or more inverters with the one or more heat transfer fluid control systems. The one or more inverters may in some cases control the current-voltage point at which the photovoltaic cells operate to optimize electrical power output from the photovoltaic-thermal solar energy collector. Heat transfer fluid used in the photovoltaic-thermal solar energy collectors may be any suitable heat transfer fluid, and in some cases is water and/or ice. In other variations, a heat transfer fluid may comprise water mixed with one or more glycols (e. g., ethylene glycol or propylene glycol). In still other variations, a heat transfer fluid may be a fluid other than water (e. g., one or more glycols such as ethylene glycol and/or propylene glycol, or a silicone oil containing heat transfer fluid).

Solar energy systems described herein may comprise more than one solar energy collector and in some cases, more than one type of solar energy collector. In some cases, an array comprising multiple solar energy collectors is used in a solar energy collector system. For example, a system may comprise 1, 2 between 2 and 10, between 10 and 20, between 20 and 30, or any other suitable number of photovoltaic-thermal solar energy collectors capable of generating electrical energy and thermal energy. Each photovoltaic-thermal solar energy collector may comprise, for example, one or more rows of coupled photovoltaic-thermal solar energy collector modules. Any suitable grouping of photovoltaic-thermal solar energy collector systems may be used to provide the desired amount of electrical energy and thermal energy. The electrical and thermal operation of individual photovoltaic-thermal solar energy collectors, or the operation of different groups of photovoltaic-thermal solar energy collectors, may be separately controlled in some cases. Thus, different photovoltaic-thermal solar energy collectors within a system may operate at different current-voltage power points, use different heat transfer fluid flow rates and temperature, or both operate at different current-voltage power points and operate using different heat transfer fluid flow rates and temperatures. It should be understood that the modules collecting thermal energy may be integral with those generating electrical energy or modules collecting thermal energy may be separate from those generating electrical energy.

A heat pump is any apparatus that uses energy to transfer heat from a colder heat source to a higher temperature heat sink. A reversible heat pump is a heat pump that, when operating in a forward direction, uses energy to transfer heat from a colder heat source to a higher temperature heat sink, and when operating in a reverse direction is capable of generating energy (e.g., electrical energy or mechanical energy) by transferring heat from a higher temperature heat source to a lower temperature heat sink. Any suitable type of heat pump may be used in the systems, methods and apparatus described herein. Non-limiting examples of heat pumps that may be used include: an air source heat pump, a water source heat pump, a ground source heat pump (which may use ground, rock, and/or a body of water as the cold reservoir), exhaust air heat pump, a hybrid heat pump using more than one cold reservoir (for example, ground and/or air may be used as the cold reservoir, depending on ambient conditions), and a geothermal heat pump.

A chiller is a heat pump that is employed to transfer heat out of a cold reservoir (colder heat source), thereby lowering the temperature of the cold reservoir. Any suitable type of chiller may be used. In some cases, a vapor-compression (e.g., reverse Rankine cycle) chiller is used. In some cases, an adsorption chiller is used. In some cases an absorption chiller is used. Additional non-limiting examples include air cycle chillers and chillers that utilize a reverse Stirling engine. Wet or dry cooled chillers may be used. In general, dry cooled chillers have lower COP (defined and discussed below).

A heat engine as used herein refers to any device or apparatus capable of generating useful work from thermal energy. The useful work may be in any form, e.g., mechanical work or electrical work. In some cases, the heat engine produces electrical energy or mechanical work that is converted to electrical energy. A heat engine may be the heat pump of the system operating in a reverse direction. A heat engine may comprise the heat pump of the system and additional components. Non-limiting examples of heat engines include Rankine cycle heat engines, e. g., organic Rankine cycle (ORC) heat engines, Brayton cycle heat engines, and Stirling cycle heat engines. Other non-limiting examples of heat engines include any type of thermoelectric device or thermoelectric generator that is capable of converting heat to electrical energy.

The performance of a heat pump may be characterized by a “coefficient of performance” (COP). The COP of a heat pump is the ratio of the heat pumped by the heat pump to the amount of work required to pump the heat. For electrically powered heat pumps, the COP is essentially the amount of heat pumped by the heat pump divided by the amount of electrical energy required by the heat pump to pump that heat. The work dissipated in the heat pump may appear as heat in the heat transfer fluid heated by the heat pump. Thus, the total amount of heat delivered by an electrically powered heat pump to a heat transfer fluid may be approximately equal to the amount of electrical energy used to pump the heat multiplied by (COP+1). That is, the heat delivered by a heat pump is approximately (COP+1) times (electric energy used to pump the heat). For electrically powered heat pumps pumping ambient heat into a heat transfer fluid (for example, water) having a temperature of about 120° C. or less, the value of the COP may be, for example, about 3 to 4. Certain chillers useful for lowering the temperature of water in a cold reservoir (e.g., from about 20° C.-40° C. to about 0° C.-10° C.) may have a COP that is about 4 or greater, about 5 or greater, or about 6 or greater, for example about 6 to 10, or about 6 to 7 (e.g., about 6.3, about 6.4, or about 6.5), or about 7 to 8, or about 8 to 9, or 9 or greater.

Referring again to FIGS. 1-7B, a ratio of heat h1 to the electric energy e1 produced by a photovoltaic-thermal solar energy collector may be varied. In some cases, a ratio h1:e1 is about 1, about 2, about 3, about 4, about 5, about 6, about 7, about 8, about 9 or about 10. In some variations, a ratio h1:e1 is about 4. If the electric output e1 of the photovoltaic-thermal solar energy collector is about one unit of energy and is used to power a heat pump having a COP of about 3-4, the heat drawn by the heat pump from a cold reservoir may be about 4 units of thermal energy. A photovoltaic-thermal solar energy system that generates 1 unit of electrical energy e1 may generate about 4 units of thermal energy h2. Thus, the combined thermal energy h1+h2 may be about 8 units of energy.

In the systems and methods of FIGS. 1-7B, at least a portion of the electricity e1 generated by a photovoltaic-thermal solar energy collector may be used to power a heat pump to draw heat h2 from a heat source (cold reservoir). In some cases, substantially all of the solar-generated electrical energy e1 is used to drive the heat pump. In other cases, only a portion of the solar-generated electrical energy e1 is used to drive the heat pump. In some cases, the heat pump is powered by a combination of externally-supplied supplemental energy e3 and electrical energy e1. External energy e3 may be from any type of supplemental energy source, including mechanical energy, energy derived from burning fossil fuels or plant-based fuels, or electrical energy (e. g., from the power grid, a generator, a battery, another solar energy collector, a wind turbine, a hydroelectric source, or the like). Electrical energy e1 generated by the photovoltaic-thermal solar energy collector that is not used to drive the heat pump may be used for any suitable purpose, for example, supplied to an external electric power grid or to some external load, or to supply power to one or more other aspects of the solar energy system, such as to a tracking system, an electronic control system, a cooling system, and/or heat transfer fluid control system.

In the systems and methods of FIGS. 1-7B, at least a portion of heat h1 generated by a photovoltaic-thermal solar energy collector and at least a portion of heat h2 drawn from the cold reservoir by the heat pump may be used to heat the hot reservoir. In some cases, substantially all of heat h1 and substantially all of heat h2 are used to heat the hot reservoir. In other cases, only a portion of heat h1 is used to heat the hot reservoir and substantially all of heat h2 is used to heat the hot reservoir, substantially all of heat h1 and only a portion of heat h2 is used to heat the reservoir, or only a portion of each of heat h1 and heat h2 are used to heat the reservoir. It is not required that heats h1 and h2 be used continuously or simultaneously to heat the hot reservoir. Instead any combination of heat h1 and h2 may be applied intermittently, or heat h1 and heat h2 may be alternately used to heat the hot reservoir. That is, there may be periods of operation in which both heat h1 and heat h2 are used, and periods of operation where only one of heat h1 and heat h2 is used for heating the reservoir. In some cases, the hot reservoir is heated by a combination of externally-supplied supplemental heat h3 and at least a portion of heat h1 and heat h2. External heat h3 may be from any type of supplemental heat source, including heat derived from burning fossil fuels or plant-based fuels, or from an additional solar thermal energy collector. Heat h1 generated by the photovoltaic-thermal solar energy collector and heat h2 that is not used to heat the hot reservoir may be used for any suitable purpose within the system or external to the system.

Any suitable cold reservoir may be used in the systems and methods. In some cases, at least a portion of the cold reservoir is the ambient environment. In some cases, the cold reservoir is the ambient environment. Optionally, the cold reservoir may be passively cooled by the environment. In some variations, the cold reservoir may be actively cooled (e. g., using a portion of electrical energy e1 and/or an external cooling source). The negative heat (cold) in the cold reservoir may in some variations be allowed to dissipate to the environment. In other variations, the cold may be stored for use. For example, the cold reservoir may comprise a vessel containing a thermal storage medium (for example, water, ice, or a mixture of water or ice) from which heat may be drawn. The cooled thermal storage medium may in some cases be used for one or more cooling applications, which may be internal to the system or external to the system. In some variations of the systems or methods, cold stored in the cold reservoir may be used for cooling a heat engine, for example, a condensing portion of a heat engine. In certain variations in which the heat engine comprises an organic Rankine cycle engine, cold from the cold reservoir may be used for cooling the organic Rankine cycle engine, for example a condensing portion of the ORC. In some systems or methods, cold in the cold reservoir may be used to cool one or more photovoltaic cells in a receiver of the photovoltaic-thermal solar energy collector. For example, the cold reservoir may be used to cool one or more photovoltaic cells to increase their efficiency to a desired level.

In general, the temperature difference between the hot and cold reservoirs affects the efficiency of a heat pump or heat engine that is used to convert thermal energy in the hot reservoir to electrical energy e2. Also, an efficiency of photovoltaic cells decreases with increasing temperature, so that in many cases a photovoltaic solar thermal energy collector is operated at a temperature that is less than 120° C. The operating temperature T_{H} of the hot reservoir and the operating temperature T_{C} of the cold reservoir may be selected to strike a desired trade-off between energy consumption of the heat pump, operation temperature of the photovoltaic-thermal solar energy collector, cost of thermal energy storage, volume of heat transfer fluid used, type and efficiency of heat engine used to convert stored thermal energy to electricity, and type of electrical demand on the final electrical output (e. g., high power bursts of electrical output, or low power extended time electrical output.)

FIG. 1 provides a flow chart illustrating methods for generating dispatchable energy. Here, method 600 comprises collecting solar energy using a concentrating photovoltaic-thermal solar energy collector (step 601) to generate electrical energy e1 (step 603) and produce useful heat h1 (step 605). The methods comprise using at least a portion of electrical energy e1 to drive a heat pump to draw heat h2 from a cold reservoir (step 607). The methods comprise heating a hot reservoir using at least a portion of heat h1 and at least a portion of heat h2 (step 609). The methods comprise generating electrical energy e2 from thermal energy in the hot reservoir (step 611). Optionally, the methods may comprise storing negative heat (cold) produced in the cold reservoir (step 613). If the cold is stored, the methods may optionally comprise cooling a heat engine used to generate electrical energy e2 from thermal energy in the hot reservoir (step 615) and/or optionally cooling one or more photovoltaic cells in the photovoltaic-thermal solar energy collector (step 617). Variations of the methods are described herein.

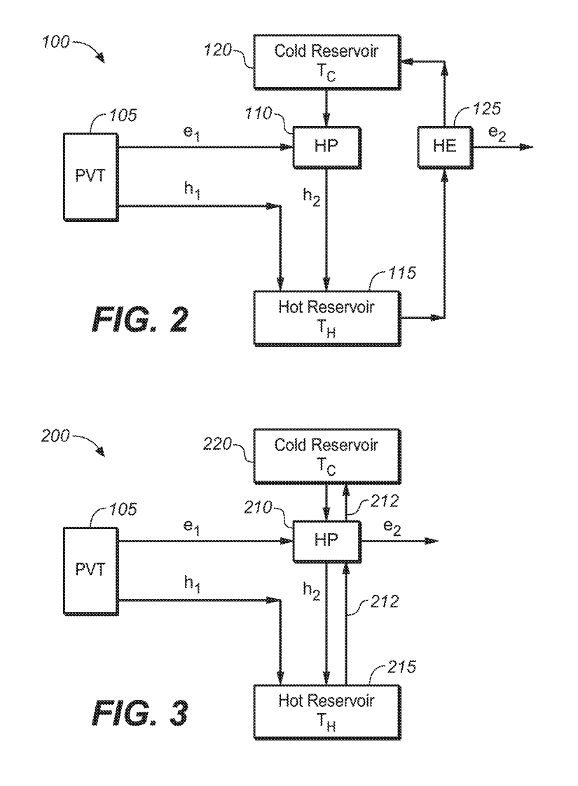

FIGS. 2, 3, 4A-4E, 5A-5B and 6 provide non-limiting examples of solar energy systems, each of which may be employed in operating variations of methods described herein. Referring now to FIG. 2, an example solar energy system 100 comprises a photovoltaic-thermal solar energy collector (PVT) 105 that generates electrical energy (e1) and thermal energy (h1). At least a portion of the electrical energy e1 generated by PVT 105 is used to drive a heat pump (HP) 110 to draw heat h2 from cold reservoir 120. At least a portion of heat h1 collected by PVT 105 and at least a portion of heat h2 drawn from the cold reservoir 120 by heat pump 110 is used to heat a hot reservoir 115. A heat engine (HE) 125 is used to generate electrical energy e2 from thermal energy in the hot reservoir 115 using a temperature difference between the hot reservoir 115 having temperature T_{H} and the cold reservoir 120 having temperature T_{C}, where T_{H}>T_{C}. Although the particular embodiment of the system illustrated in FIG. 2 depicts the heat pump 110 and the heat engine 125 as separate units, it should be understood that the heat pump and heat engine may be combined into an integral unit or operated as separate units. As illustrated below in FIG. 3, in some cases, the heat engine may be or may comprise the heat pump operated in a reverse manner so that heat is transferred from the hot reservoir to the cold reservoir to generate electrical energy e2. The generated electrical energy e2 is dispatchable and may be used as it is generated or may be generated at a time delayed relative to the generation of electrical energy e1. If generation of electrical energy e2 is to be delayed, thermal energy may be stored in the hot reservoir 115 until a desired time at which the heat engine 125 may be operated to generate electrical energy output e2. For example, electrical energy e2 may be generated by system 100 during periods of darkness or low solar output due the weather, shading, season of the year, or maintenance of the solar collector, and the like. Electrical energy e2 may be used to increase electrical energy output during high demand periods.

Referring now to FIG. 3, an example system 200 is shown in which the heat engine is or comprises a heat pump operating in a reverse operation (as shown by arrows 212) to generate electrical energy e2 from a temperature difference between the hot reservoir having temperature T_{H} and the cold reservoir having temperature T_{C}. The system 200 comprises a photovoltaic-thermal solar energy collector (PVT) 105 that is capable of generating electrical energy (e1) and thermal energy (h1). At least a portion of the electrical energy e1 generated by the PVT is used to drive a heat pump (HP) 210 to draw heat h2 from cold reservoir 220. At least a portion of heat h1 and at least a portion of heat h2 are used to heat a hot reservoir 215 to a temperature T_{H}. The heat pump 210 is operated in a reverse operation (as shown by arrows 212) to generate dispatchable electrical energy e2 from the temperature difference between the hot reservoir at temperature T_{H} and the cold reservoir 220 at temperature T_{C}, where T_{H}>T_{C}. If generation of electrical energy e2 is to be delayed, thermal energy may be stored in the hot reservoir 115 until a desired time at which the heat pump 210 may be operated to generate electrical energy output e2. For example, electrical energy e2 may be generated by system 200 during periods of darkness or low solar output due the weather, shading, season of the year, or maintenance of the solar collector, and the like. Electrical energy e2 may be used to increase electrical energy output during high demand periods.

The systems, methods and apparatus of FIGS. 1-7B may employ one or more heat transfer fluids for carrying heat h1 generated by the photovoltaic-thermal solar energy collector and/or heat h2 drawn from the cold reservoir. For example, a system or method may utilize any one of or any combination of the following: a) a heat transfer fluid HTF1 that, in operation, flows through one or more fluid channels in the photovoltaic-thermal solar energy collector to collect heat h1; and b) a heat transfer fluid HTF2 that, in operation, carries heat h2 from the heat pump.

Certain variations of the systems, methods and apparatus of FIGS. 1-7B use a heat transfer fluid HTF1 for carrying heat h1 from the photovoltaic-thermal solar energy collector and a heat transfer fluid HTF2 for carrying heat h2 from the heat pump. During operation of some variations of the systems or methods, heat transfer fluid HTF1 carrying heat h1 has a temperature T1 that is greater than a temperature T2 of heat transfer fluid HTF2 carrying h2. During operation of other variations of the systems or methods, heat transfer fluid HTF1 carrying heat h1 has a temperature T1 that is less than a temperature T2 of heat transfer fluid carrying h2. In some cases, operation of the systems or methods results in heat transfer fluid HTF1 carrying heat h1 having a temperature T1 that is approximately equal to temperature T2 of heat transfer fluid HTF2 carrying heat h2.

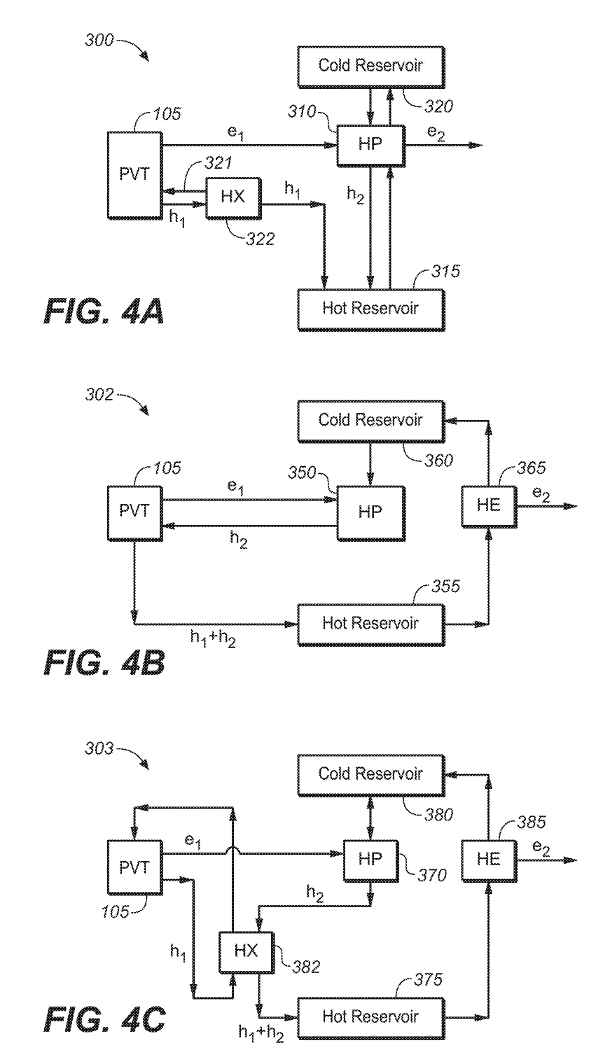

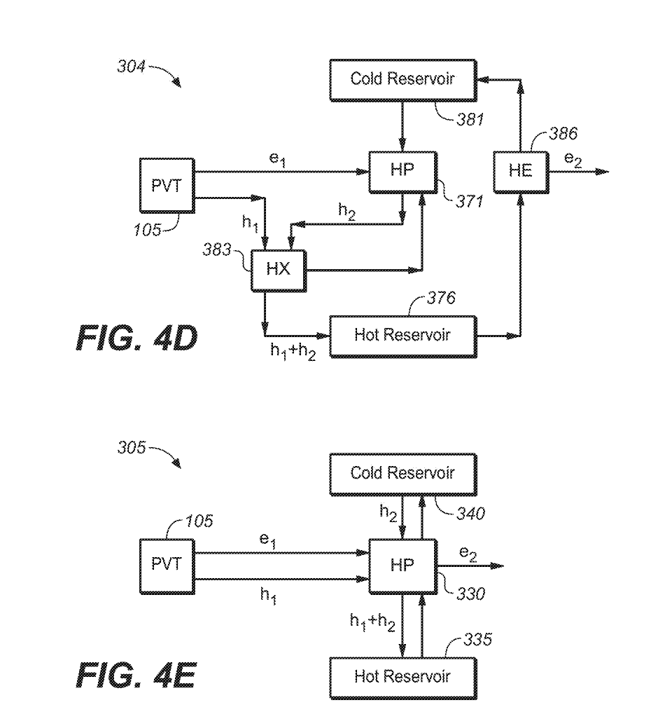

Optionally, the systems, methods and apparatus of FIGS. 1-7B may use one or more heat exchangers. For example, a system or method may use one of or any combination of the following heat exchangers: a) a heat exchanger for transferring heat h1 from the photovoltaic-thermal solar energy collector to the hot reservoir; b) a heat exchanger for transferring heat h2 from the heat pump to the hot reservoir; and c) a heat exchanger for transferring heat between a heat between a heat transfer fluid HTF1 carry heat h1 from the photovoltaic-thermal solar energy collector and a heat transfer fluid HTF2 carrying heat h2 from the heat pump. A non-limiting example of a) is provided in FIG. 4A, which is discussed in more detail below. Non-limiting examples of c) are illustrated in FIGS. 4C-4D, which are discussed in more detail below.

A variety of system configurations and methods may be used for combining heat h1 with heat h2 for heating the hot reservoir using one or more heat transfer fluids. In some variations, a heat transfer fluid carrying heat h1 and a heat transfer fluid carrying heat h2 may be mixed in the hot reservoir, or the fluids may be mixed and the combined heat transferred to the hot reservoir via heat exchange. Mixing of the heat transfer fluids may be used to combine heats h1 and h2, for example, in situations in which the temperatures of the heat transfer fluids are similar. In some variations, a heat exchanger is used to transfer heat from a heat transfer fluid HTF1 carrying heat h1 from the photovoltaic-thermal solar energy collector to another heat transfer fluid HTF3, and HTF3 and HTF2 are mixed to combine heats h1 and h2 for use in heating the hot reservoir. This option allows heat transfer fluid HTF1 to be recirculated back to the photovoltaic-thermal solar energy collector in a closed or open recirculation loop. In other variations, a heat exchanger is used to transfer heat from a heat transfer fluid HTF2 carrying heat h2 from the heat pump to another heat transfer fluid HTF4, and HTF4 and HTF1 are mixed to combine heats h1 and h2 for heating the reservoir. This option allows heat transfer fluid HTF2 to be recirculated back to the heat pump in an open or closed recirculation loop. In still other variations, a heat exchanger is used to transfer heat h1 from HTF1 to another heat transfer fluid HTF3, a heat exchanger is used to transfer heat h2 from HTF2 to another heat transfer fluid HTF4, and fluids HTF3 and HTF4 are mixed to combine heats h1 and h2 for use in heating the hot reservoir. This option allows recirculation of heat transfer fluid HTF1 back to the photovoltaic-thermal solar energy collector, and recirculation of heat transfer fluid HTF2 back to the heat pump.

A non-limiting example of a system in which a heat transfer fluid carrying heat h1 and a heat transfer fluid carrying heat h2 are mixed to heat the hot reservoir is provided in FIG. 4A. Here, in system 300, a heat transfer fluid HTF1 flows through one or more fluid channels in photovoltaic-thermal solar energy collector 105 to collect heat h1. Heat pump 310 draws heat h2 from cold reservoir 320. The heat transfer fluid HTF1 carrying heat h1 passes through a heat exchanger (HX) 322 and transfers heat h1 to heat transfer fluid HTF3. Heat transfer fluid HTF1 may flow in an open or closed recirculation loop 321 through one or more fluid channels in the PVT 105 and the heat exchanger 322. Heat transfer fluid HTF3 carrying h1 and heat h2 drawn by heat pump 310 are combined and used to heat the hot reservoir 315. Dispatchable electrical energy e2 is generated from thermal energy in the hot reservoir 315 using the temperature difference between the hot reservoir 315 and cold reservoir 320 by a heat engine. In this particular embodiment, the heat engine comprises the heat pump 310 operating in a reverse mode. Although not shown in FIG. 4A, a heat engine may be used to generate electrical energy e2 from thermal energy in the hot reservoir 315 using the temperature difference between the hot and cold reservoirs. The heat engine may be separate from the heat pump or the heat engine and heat pump may be integrated into a single unit. Any suitable heat engine may be used. In some cases, an organic Rankine cycle heat engine is used. In some variations, an integrated unit comprising an organic Rankine cycle heat engine and a heat pump is used. Optionally, a heat transfer fluid HTF2 may be used to carry heat h2 and a mixture of heat transfer fluids HTF2 and HTF3 be used to heat the hot reservoir 315 via heat exchange. In another variation of the example shown in FIG. 4A, the heat exchanger 322 is eliminated, and heat transfer fluid HTF1 is mixed with heat transfer fluid HTF2 so that the combined heats h1 and h2 are used to heat the hot reservoir.

In some variations of the systems and methods of FIGS. 1-7B, thermal energy generated in the photovoltaic-thermal solar energy collector is used to boost the thermal energy of a heat transfer fluid carrying heat h2 drawn from the cold reservoir by the heat pump. For example, a heat transfer fluid HTF1 carrying heat h1 from the photovoltaic-thermal solar energy collector and having temperature T1 transfers heat via a heat exchanger to a heat transfer fluid HTF2 carrying heat h2 from the heat pump and having temperature T2 that is less than T1. Following heat exchange, the heat transfer fluid HTF2 carries heat h1+h2 (minus possible heat losses from transfer inefficiency) that is used to heat the hot reservoir. Optionally, the heat transfer fluid HTF1 may be recirculated through one or more fluid channels in the photovoltaic-thermal solar energy collector and the heat exchanger in an open or closed recirculation loop. In another example, a heat transfer fluid HTF2 heated by the heat pump and carrying heat h2 flows through one or more fluid channels in the photovoltaic-thermal solar energy collector to collect additional heat h1. Following thermal boosting by passage through the photovoltaic-thermal solar energy collector, heat transfer fluid HTF2 carries heat h2+h1, which is used to heat the hot reservoir.

Non-limiting examples of systems in which the photovoltaic-thermal solar energy collector is used to boost the thermal energy of a heat transfer fluid carrying h2 from the heat pump are illustrated in FIG. 4B and FIG. 4C. Referring first to FIG. 4B, system 302 comprises photovoltaic-thermal solar energy collector 105 that generates electrical energy e1 and thermal energy h1. At least a portion of electrical energy e1 is used to drive a heat pump HP 350 to draw heat h2 from cold reservoir 360. A heat transfer fluid HTF2 at temperature T2 carries heat h2 and flows through one or more fluid channels in the photovoltaic-thermal solar energy collector to collect h1 and increase in thermal energy. The temperature of HTF2 may be increased to a temperature T2′ that is greater than T2. The heat transfer fluid HTF2 carries thermal energy h1+h2 and is used to heat the hot reservoir 355. A heat engine 365 is used to convert thermal energy in the hot reservoir 355 to electrical energy e2 using the difference in temperatures between the hot and cold reservoirs. In some variations of the embodiment illustrated in FIG. 4B, the heat pump 350 operating in reverse functions as the heat engine to convert thermal energy in the hot reservoir to electrical energy e2. In certain variations, the heat engine 365 is or comprises an organic Rankine cycle engine. In some variations, the heat pump and the heat engine are integrated into a single unit.

Referring now to FIG. 4C, system 303 comprises photovoltaic-thermal solar energy collector 105 generating electrical energy e1 and thermal energy h1. A heat transfer fluid HTF1 flows through one or more fluid channels in photovoltaic-thermal solar energy collector 105 to collect heat h1. Heat pump 370 is driven at least in part with electrical energy e1 to draw heat h2 from cold reservoir 380. A heat transfer fluid HTF2 is used to collect heat h2. Heat transfer fluid HTF1 and heat transfer fluid HTF2 pass through heat exchanger 382 so that thermal energy is transferred from one heat transfer fluid to the other. Heat transfer fluid HTF1 is used to boost the thermal energy of heat transfer fluid HTF2, and the thermally boosted HTF2 carrying the combined heats represented by h1+h2 is used to heat the hot reservoir 375. Heat engine 385 converts thermal energy in hot reservoir 375 to electrical energy e2 using the temperature difference between the hot reservoir 375 and cold reservoir 380. Optionally, heat transfer fluid HTF1 flows in a closed or open recirculation loop to the photovoltaic-thermal solar energy collector after exiting the heat exchanger 382. In some variations of the embodiment illustrated in FIG. 4C, the heat pump 370 operating in reverse functions as the heat engine to convert thermal energy in the hot reservoir 375 to electrical energy e2. In certain variations, the heat engine 385 is or comprises an organic Rankine cycle engine. In some variations, the heat pump 370 and the heat engine 385 are integrated into a single unit.

In some variations of the systems and methods of FIGS. 1-7B, the heat pump is used to boost the thermal energy of a heat transfer fluid carrying heat h1 from the photovoltaic-thermal solar energy collector. Such variations may be used, for example, so that the temperature of the hot reservoir is not limited by the temperature at which the photovoltaic cells in the solar receiver may be operated with useful efficiency. In one example, heat transfer fluid HTF2 carrying heat h2 from the heat pump and having temperature T2 transfers heat via heat exchanger to a heat transfer fluid HTF1 carrying heat h1 and having temperature T1 that is less than T2. Following heat exchange, heat transfer fluid HTF1 carries heat h1+h2 (minus possible heat loss due to transfer inefficiency) that is used to heat the hot reservoir. In another example, a heat pump draws heat h1 from a heat transfer fluid HTF1 that collects heat from the photovoltaic-thermal solar energy collector. The heat pump draws heat h2 from the cold reservoir. A heat transfer fluid HTF2 carrying the combined heat h1+h2 from the heat pump is used to heat the hot reservoir.

Non-limiting examples of systems in which the heat pump is used to boost the thermal energy of a heat transfer fluid carrying heat h1 from the photovoltaic-thermal solar energy collector are provided in FIG. 4D and FIG. 4E. Referring first to FIG. 4E, system 305 comprises photovoltaic-thermal solar energy collector 105 that generates electrical energy e1 and heat h1. Electrical energy e1 is used to supply at least a portion of the power used to drive heat pump 330 that draws heat h2 from a cold reservoir 340. Heat pump 330 draws heat h1 from PVT 105. A heat transfer fluid HTF2 carrying heat from both the cold reservoir and the PVT 105 (represented as h1+h2 in FIG. 4E) is used to heat a hot reservoir 335. Thermal energy in the hot reservoir is converted to electrical energy e2 by heat pump 330 operating in reverse and using the temperature difference between the hot reservoir 335 and the cold reservoir 340. Although not shown in FIG. 4E, a heat engine may be used to generate electrical energy e2 from thermal energy in the hot reservoir 335 using the temperature difference between the hot and cold reservoirs. The heat engine may be separate from the heat pump or the heat engine and heat pump may be integrated into a single unit. Any suitable heat engine may be used. In some cases, an organic Rankine cycle heat engine is used. In some variations, an integrated unit comprising an organic Rankine cycle heat engine and a heat pump is used.

Referring now to FIG. 4D, system 304 comprises a photovoltaic-thermal solar energy collector 105 that generates electrical energy e1 and heat h1. Heat transfer fluid HTF1 flows through one or more fluid channels in PVT 105 to collect heat h1. In operation, heat transfer fluid HTF1 has temperature T1. Electrical energy e1 is used to supply at least a portion of the power to drive heat pump 371 to draw heat h2 from cold reservoir 381. Heat transfer fluid HTF2 carries heat h2 from the heat pump and has temperature T2. Heat transfer fluid HTF2 transfers heat to heat transfer fluid HTF1 via heat exchanger 383 to boost the thermal energy of heat transfer fluid HTF1 so that its temperature is increased from T1 to T1′. Heat transfer fluid HTF1 carrying heat h1 and heat h2 (represented as h1+h2) and having temperature T1′ is used to heat the hot reservoir 376. A heat engine 386 is used to convert thermal energy in hot reservoir 376 to electrical energy e2. In some variations of the embodiment illustrated in FIG. 4D, the heat pump 371 operating in reverse functions as the heat engine to convert thermal energy in the hot reservoir to electrical energy e2. In certain variations, the heat engine 386 is or comprises an organic Rankine cycle engine. In some variations, the heat pump 371 and the heat engine 386 are integrated into a single unit. If the system is operated so that heat transfer fluid HTF1 has greater thermal energy than heat transfer fluid HTF2, then heat transfer fluid HTF1 may be used to boost the thermal energy of heat transfer fluid HTF2. For example, if heat transfer fluid HTF1 has temperature T1 and heat transfer fluid HTF2 has temperature T2 where T2<T1, then heat transfer fluid HTF1 may boost the temperature T2 of heat transfer fluid HTF2 to a temperature T2′ higher than T2.

In the systems and methods of FIGS. 1-7B, the operating temperatures of the cold reservoir, hot reservoir, photovoltaic portion of the receiver, heat transfer fluid HTF1 flowing through one or more channels of the solar thermal portion of the receiver, heat transfer fluid HTF2 carrying heat h2 from the heat pump, and fluid volume may be selected and optimized for any one of or any combination of factors, including: efficiency of electricity generated in the solar receiver by the photovoltaic cells; energy required by the heat pump to create the hot and cold reservoirs; efficiency of the heat engine to convert thermal energy to electricity; thermal losses to environment; cost of materials; and cost and volume of heat storage. For example, in some variations, the hot reservoir may have a temperature of about 120° C., and the cold reservoir may have a temperature of about 50° C., 40° C., 30° C., 25° C., or 20° C. In some variations, the hot reservoir may have a temperature of about 110° C. and the cold reservoir may be at about 50° C., 40° C., 30° C., 25° C., or 20° C. In some variations, the hot reservoir may have a temperature of about 100° C. and the cold reservoir may have a temperature of about 50° C., 40° C., 30° C., 25° C., or 20° C. In some variations, the hot reservoir may have a temperature of about 90° C. and the cold reservoir may have a temperature of about 50° C., 40° C., 30° C., 25° C., or 20° C. In some variations, the hot reservoir may have a temperature of about 80° C. and the cold reservoir may have a temperature of about 50° C., 40° C., 30° C., 25° C., or 20° C.

The systems and methods of FIGS. 1-7B may employ a variety of schemes by which the heat pump is driven at least in part using electrical energy e1 generated by the photovoltaic-thermal solar energy collector. In some cases, substantially all of the electrical energy e1 generated is used to drive the heat pump. In other variations, a portion of electrical energy e1 is used for one or more other applications, which may be internal applications within the solar energy system or external applications outside of the system. In certain variations, external energy e3 from an external energy source is used in combination with electrical energy e1 to drive the heat pump. External energy e3 may be any type of energy, including mechanical energy, energy derived from burning fossil fuels or plant-based fuels, or electrical energy (e. g., from the power grid, a generator, a battery, another solar energy collector, a wind turbine, a hydroelectric source, or the like). When external energy e3 is used in combination with electrical energy e1 to drive the heat pump, e1 and e3 may be used in any suitable relative amounts. For example, electrical energy e1 and e3 may be used to drive the heat pump where e1 and e3 are used in a ratio e1:e3 of about 1:1000, about 1:800, about 1:500, about 1:200, about 1:100, about 1:50. about 1:20, about 1:10, about 1:5, about 1:3, about 1:2, about 1:1, about 2:1, about 3:1, about 5:1, about 10:1, about 20:1, about 50:1, about 100:1, about 200:1, about 500:1, about 800:1 or about 1000:1. When external energy e3 and electrical energy e1 are used to drive the heat pump, the energy sources may be combined in any suitable manner. For example, e1 and e3 may be used in a parallel operation so that both e1 and e3 are supplied simultaneously to the heat pump in any relative amounts. The relative amounts of e1 and e3 need not stay constant with time, and may be adjusted according to operating conditions (e. g., time of day, weather, season and/or demand). In other operating modes, e1 and e3 may be alternately supplied to heat the heat pump, so when e1 is supplied e3 is not supplied, and when e3 is supplied e1 is not supplied. Any suitable scheme for alternating e1 and e3 may be used. The alternating may occur at regular intervals or irregular intervals (e. g., irregular intervals determined by an operator based on operating conditions or demand). If e1 and e3 are alternated at regular intervals, the frequency at which they are alternated may be any suitable frequency, and the frequency of alternating may be constant or non-constant (e. g., adjusted during operation to accommodate operating conditions, such as time of day, weather, season, and/or demand). For example, e1 may be used to drive the heat pump during sunlight hours and e3 may be used to drive the heat pump during darkness or cloud cover. Durations of alternating intervals may be adjusted, for example, seasonally.

The systems and methods of FIGS. 1-7B may employ a variety of schemes by which the hot reservoir is heated at least in part using heat h1 from the photovoltaic-thermal solar energy collector and heat h2 from the heat pump. Any suitable relative quantities of heat h2 from the heat pump and heat h1 from the photovoltaic-thermal solar energy collector to heat the hot reservoir. For example, heat h1 and heat h2 may be combined in a ratio h1:h2 to heat the hot reservoir, where h1:h2 may be about 1:100, about 1:50, about 1:10, about 1:5, about 1:2, about 1:1, about 2:1, about 5:1, about 10:1, about 50:1, or about 100:1. In some variations of the systems and methods, heat h1 and heat h2 may be combined in a 1:1 ratio. During operation, a ratio h1:h2 may or may not be held constant. In some variations, a ratio h1:h2 is adjusted according to operating conditions (e. g., time of day, season, weather, temperature, and demand).

In some cases, substantially all of heat h1 generated by the photovoltaic-thermal solar energy collector and substantially all of heat h2 drawn by the heat pump is used to heat the hot reservoir. In other cases, only a portion of heat h1 and substantially all of heat h2 are used, or substantially all of heat h1 and only a portion of heat h2 are used, or only a portion of heat h1 and only a portion of heat h2 are used. Portions of heat h1 or heat h2 that are not used to heat the hot reservoir may be used for one or more other applications, which may be internal applications within the solar energy system or external applications outside of the system. In certain variations, external heat h3 from an external energy source is used in combination with heat h1 and heat h2 to heat the hot reservoir. External heat h3 may be derived from any type of energy, including mechanical energy, energy derived from burning fossil fuels or plant-based fuels, or electrical energy (e. g., from the power grid, a generator, a battery, another solar energy collector, a wind turbine, a hydroelectric source, or the like). When external heat h3 is used in combination with heat h1 and heat h2 to heat the hot reservoir, heat h1, heat h2 and heat h3 may be used in any suitable relative amounts. For example, heat h1, heat h2 and heat h3 may be used to heat the hot reservoir where (h1+h2) and h3 are used in a ratio (h1+h2):h3 of about 1:1000, about 1:800, about 1:500, about 1:200, about 1:100, about 1:50. about 1:20, about 1:10, about 1:5, about 1:3, about 1:2, about 1:1, about 2:1, about 3:1, about 5:1, about 10:1, about 20:1, about 50:1, about 100:1, about 200:1, about 500:1, about 800:1 or about 1000:1. The relative amounts of heats h1, h2 and h3 need not stay constant with time, and may be adjusted according to operating conditions (e. g., time of day, weather, season and/or demand). When external heat h3 and h1+h2 are used to heat the hot reservoir, the heat sources may be combined in any suitable manner. For example, heat h1, heat h2 and heat h3 may be applied in a parallel operation so that all three heat sources are supplied simultaneously to the hot reservoir in any relative amounts. In other operating modes, heats h1, h2, and h3 may be alternately supplied to hot reservoir, or any combination of any two of heats h1, h2, and h3 may be alternated with the third heat source to heat the hot reservoir. For example, a combined heat h1+h2 may be alternately supplied with heat h3 to the hot reservoir. Any suitable scheme for alternating supply of the various heat sources may be used. The alternating may occur at regular intervals or irregular intervals (e. g., irregular intervals determined by an operator based on operating conditions or demand). Regular or irregular intervals may have any suitable duration, and the frequency of alternating may be constant or non-constant (e. g., adjusted during operation to accommodate operating conditions, such as time of day, weather, season, and/or demand).

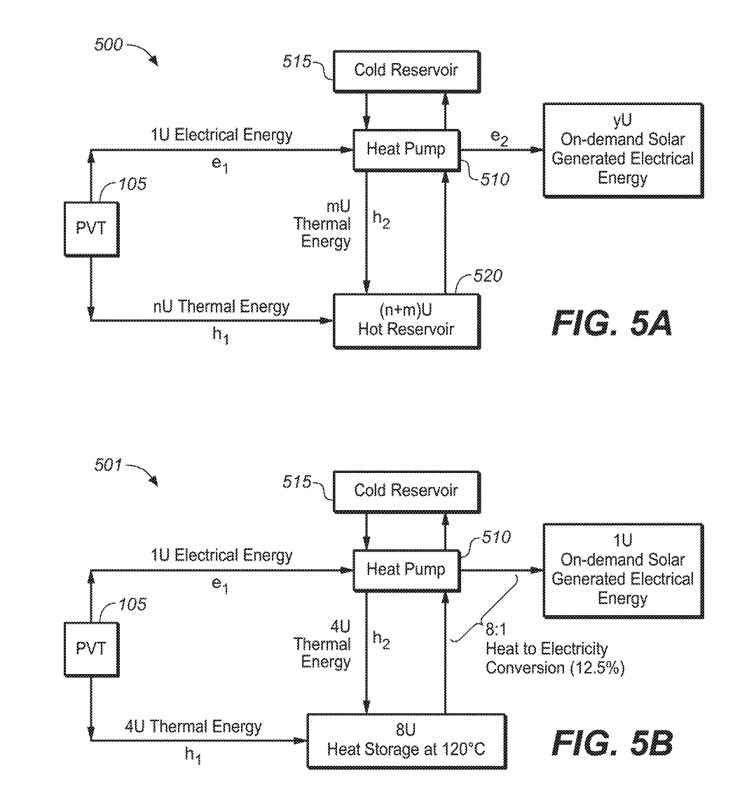

Referring now to FIG. 5A, a photovoltaic-thermal solar energy collector 105 produces 1 unit (U) of electrical energy e1 and n units of thermal energy h1. Electrical energy e1 is used to power a heat pump 510 to draw h2, which is m units of thermal energy, from the cold reservoir 515. Heat h1 and heat h2 are used to heat the hot reservoir 520, so that it has approximately (n+m) units of thermal energy. A heat engine (not shown) and/or a heat pump operating in reverse may be used to convert the (n+m) units of thermal energy in the hot reservoir to y units of electrical energy using the temperature difference between the hot reservoir and the cold reservoir. The photovoltaic-thermal solar energy collector 105 in system 500 may be configured so that a desired number n units of heat h1 are produced relative to the unit of electrical energy e1 produced, for example n may be about 1 unit, about 2 units, about 3 units, about 4 units, about 5 units, about 6 units, about 7 units, about 8 units, about 9 units, or about 10 units of energy when 1 unit of electrical energy e1 is produced. The system 500 may be configured so that a desired number m units of heat h2 are produced by the heat pump powered by 1 unit of electrical energy e1 generated. For example, m may about 1 unit, about 2 units, about 3 units, about 4 units, about 5 units, about 6 units, about 7 units, about 8 units, about 9 units or about 10 units. The combined heat energy used to heat the hot reservoir 520 is (n+m) units. The quantity (n+m) may be any suitable number of units of energy, for example, (n+m) may be about 2 units, about 3 units, about 4 units, about 5units, about 6 units, about 7 units, about 8 units, about 9 units, about 10 units, about 11 units, about 12 units, about 13 units, about 14 units, about 15 units, about 16 units, about 17 units, about 18 units, about 19 units, or about 20 units. The number y units of dispatchable electrical energy e2 produced depends on (n+m), the temperatures of the hot and cold reservoirs, and the efficiency of the heat pump. FIG. 5B shows a specific example of a system 501 in which n=4, m=4, (n+m)=8, and an efficiency of 12.5% for converting heat energy in the hot reservoir to electrical energy e2, so that y=1 unit. That is, the system 501 illustrated in FIG. 5B generates an amount of dispatchable energy e2 that is approximately equal to the amount of electrical energy e1 generated by the photovoltaic-thermal solar energy collector.

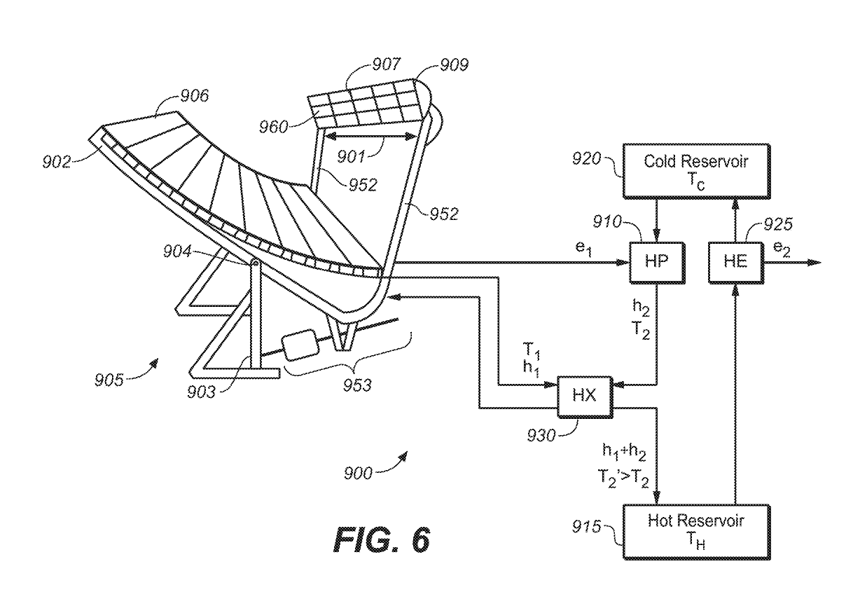

Referring now to FIG. 6, a non-limiting example of a solar energy system capable of generating dispatchable energy e2 is shown. In this example, system 900 comprises photovoltaic-thermal solar energy collector 905, a cold reservoir 920, a hot reservoir 915, a heat pump 910, and a heat engine 925. The photovoltaic-thermal solar energy collector 905 comprises a concentrating solar reflector 906 mounted on a support 902. The reflected sunlight is directed towards and focused on receiver 907 which is mounted on arms 952 of support 902. Support 902 is pivotally coupled to base supports 903 at pivot points 904. Rotation about pivot points 904 enables positioning of the reflector 906, for example rotation of the reflector for tracking of the sun. Receiver 907 rotates with reflector 906 as support 902 is rotated. Optionally, receiver 907 may be rotated about pivot points 909 to optimize collection of the reflected light. Rotation about pivot points 904 may be accomplished using any suitable mechanism. For example, a linear actuator 953 coupled to support 902 may be used to drive rotation about the pivot points 904 so that reflector 906 tracks the sun. Alternatively, supports 902 may be mounted to a rotationally driven torque tube having a rotational axis passing through pivot points 904. In this particular example, the concentrating reflector 906 concentrates the reflected sunlight into an approximately linear focus on receiver 907. The receiver 907 comprises photovoltaic cells (not shown) on surface 960 facing the reflector 906, and one or more fluid channels (not shown) extending approximately along the length 901 of the receiver 907. Heat transfer fluid may be circulated through the one or more fluid channels to collect heat. Although a single reflector/receiver/support module is shown in FIG. 6, the photovoltaic-thermal solar collector 905 may comprise multiple reflector/receiver/support modules arranged in a variety of configurations. For example, a series of multiple reflector/receiver/support modules may be arranged lengthwise (parallel to length 901) to form a row of modules. In some cases, multiple rows of modules may be arranged to form a solar collector. The modules may be coupled together in any manner to collect electrical energy produced by the photovoltaic cells and heat collected by the heat transfer fluid traveling through the receivers. Any other suitable photovoltaic-thermal solar energy collector may be used in addition to or in place of the particular photovoltaic-thermal solar collector illustrated in FIG. 6.

The photovoltaic-thermal solar energy collector 905 in the example of FIG. 6 generates electrical energy e1 via photovoltaic cells in the receiver 907 and heat h1 that is collected and carried by a heat transfer fluid HTF1 circulating through one or more fluid channels in receiver 907. At least a portion of the electrical energy e1 is used to power a heat pump 910. In some cases, only electrical energy e1 is used to drive the heat pump, and in some cases, a combination of electrical energy e1 and external energy e3 (e. g., external electrical energy from the power grid, another solar energy collector, a generator, a battery, wind turbine, hydroelectric source, or the like, or another energy source such as energy derived from burning a fossil fuel or a plant-based fuel) is used to power the heat pump. The heat pump draws heat h2 from cold reservoir 920. A heat transfer fluid HTF2 carries heat h2. Heat transfer fluid HTF1 having a temperature T1 and heat transfer fluid HTF2 and a temperature T2 pass through heat exchanger 930. In some variations, T1>T2 so that the thermal energy carried by heat transfer fluid HTF2 is boosted so that its temperature increases to T2′>T2. Heat transfer fluid HTF2 exits heat exchanger 930 carrying heat from heat pump 910 and heat from PVT 105, represented as h1+h2, and heats a hot reservoir 915. Thermal energy in the hot reservoir is converted to dispatchable electrical energy e2 by heat engine 925 (which may be or may comprise heat pump 910 operated in a reverse direction) using the temperature difference between temperature T_{H} of the hot reservoir 915 and T_{C} of the cold reservoir 920, where T_{H}>T_{C}.

In one example, the efficiency of the solar collector 905 may be about 75% energy production. Of the energy produced, about 15% is in the form of electrical energy e1 and 60% in the form of thermal energy h1, so that h1 is approximately 4 times e1 (using equivalent energy units). In some cases, the heat transfer fluid stream carrying thermal energy h1 from the receiver 907 may have a temperature T1 as high as 120° C. Any portion of or all of a conduit system that carries heat transfer fluid throughout system 905 may be pressurized so that desired temperatures are reached. For example, if water is used as a heat transfer fluid, conduits carrying water may be pressurized to enable operation at 120° C. Heat pump 910, powered by electrical energy e2, may have a COP of about 3 to 4, so about 1 unit of solar-generated electrical energy e1 is used to generate about 4 units of thermal energy h2. Heat pump 910 may be used so that the temperature T2 of the heat transfer fluid HTF2 carrying heat h2 is about 80° C. and a temperature T_{C} of the cold reservoir is about 40° C. Heat transfer fluid HTF2 passes through heat exchanger 930 where heat h1 from the photovoltaic-thermal solar energy collector boosts the thermal energy of HTF2 and boosts its temperature to T2′>T2. T2′ may be as high as T1, so that if T1=120° C., then T2′ may be approximated as 120° C., and the temperature of the hot reservoir T_{H} may be approximated as 120° C. If substantially all the heat h1 collected from receiver 907 is transferred to the heat transfer fluid HTF2 via heat exchanger 930, then heat transfer fluid carries heat h1+h2 to heat the hot reservoir 915. In this particular example, h1+h2 is approximately 8 times the solar-generated electrical energy e1. The thermal energy stored in the hot reservoir at temperature T_{H} may be converted to electrical energy using any suitable means. In some cases, a heat pump (for example, heat pump 910 operating in reverse), a heat engine (for example, an organic Rankine cycle heat engine), or a combination heat pump/organic Rankine cycle (which may comprise a separate heat pump combined with a separate organic Rankine cycle, or which may comprise an integral unit in which the heat pump and organic Rankine cycle are combined) may be used. In a system using water as a heat transfer fluid, if an organic Rankine cycle transfers heat from a hot reservoir having temperature T_{H}=120° C. to a cold reservoir having temperature T_{C}=40° C., an overall efficiency of about 12.5% for conversion of heat to electricity may be achieved, so that the thermal energy h1+h2 which is approximately 8 times e1 may be converted to e1 units of electrical energy. The example in FIG. 6 illustrates one scheme whereby approximately 100% dispatchable electrical energy may be generated using a solar-powered heat pump and solar-generated thermal energy to create a thermal storage reservoir. The thermal energy stored in the reservoir may be inexpensively and efficiently stored, for example, in one or more fluid tanks that may or may not be pressurized relative to ambient pressure.

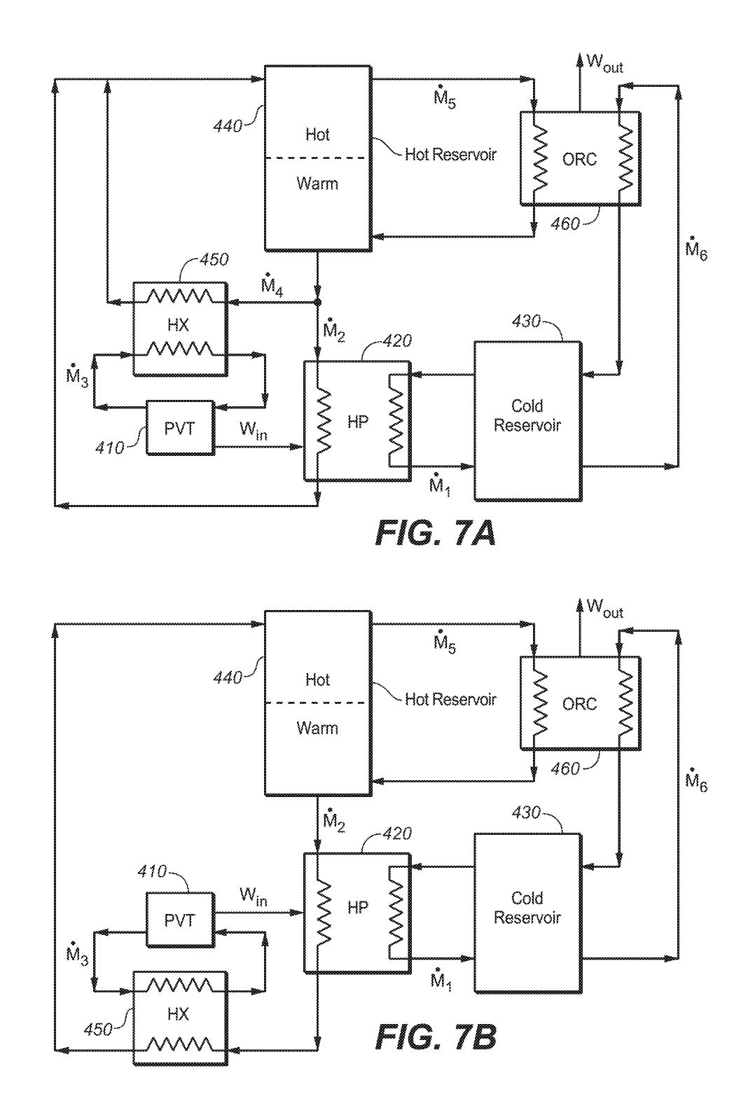

FIGS. 2-6 primarily show the flow of electrical energy and heat through various systems, with the corresponding coolant flow through these systems described in related text in this specification but not shown in detail in the figures. FIGS. 7A and 7B show coolant flow through such systems in more detail. As is conventional, in these figures various portions of the coolant flow are labeled with a dot over an “m” to indicated the time derivative of mass, i.e., mass flow \dot{m}₁, \dot{m}₂, and so forth.

In the variation shown in FIG. 7A, when solar energy is available the PVT collector 410 provides electrical energy Wᵢₙ (“work in”) to drive heat pump 420. Heat pump 420 moves heat from a flow of heat transfer fluid \dot{m}₁ drawn from cold reservoir 430 to a flow of heat transfer fluid \dot{m}₂ drawn from hot reservoir 440. The heat transfer fluid stored in hot reservoir 440 may be stratified or partially stratified by temperature, with hotter fluid above cooler fluid. In such cases, heat transfer fluid provided from the hot reservoir to the heat pump may be preferably drawn from the cooler strata, as shown. Also when solar energy is available, a flow of heat transfer fluid \dot{m}₃ heated in the PVT collector may be circulated through a heat exchanger 450, which transfers heat from \dot{m}₃ to another flow of heat transfer fluid \dot{m}₄ drawn from hot reservoir 440. (Flow \dot{m}₄ may also be drawn preferably from cooler strata in the hot reservoir, as shown). After heating, heat transfer fluid flows \dot{m}₂ and \dot{m}₄ return to hot reservoir 440 for storage, and may preferably be returned to hot strata within the storage, as shown. Whether or not solar energy is available, a heat engine such as ORC heat engine 460 may transfer heat from a flow of heat transfer fluid \dot{m}₅ drawn from hot reservoir 440 to a lower temperature flow of heat transfer fluid \dot{m}₆ drawn from cold reservoir 430, thereby generating electrical energy Wₒᵤₜ (“work out”). Coolant flow cycles from the hot reservoir through the heat pump, the heat exchanger, and through the ORC heat engine may operate independently of each other.

In the system illustrated in FIG. 7A, heat pump 420 and heat exchanger 450 are arranged in parallel. The system illustrated in FIG. 7B is essentially the same as that of FIG. 7A, except that in FIG. 7B heat pump 420 and heat exchanger 450 are arranged in series with heat exchanger 450 downstream from heat pump 420. In the arrangement of FIG. 7B, a flow of heat transfer fluid \dot{m}₂ drawn from hot reservoir 440 is initially heated by heat pump 420 to a first temperature, and then is further heated to a higher temperature in heat exchanger 450 by heat collected by PVT 410. Alternatively, heat exchanger 450 and heat pump 420 may be arranged in series with heat pump 420 downstream from heat exchanger 450. In that arrangement, the flow of heat transfer fluid \dot{m}₂ drawn from hot reservoir 440 is initially heated by heat exchanger 450 to a first temperature with heat collected by PVT 410, and then is further heated to a higher temperature by heat pump 420.

Non-limiting examples of additional systems and methods are illustrated in FIGS. 8A, 8B, 9A, 9B, 10, 11, and 12. Referring first to FIG. 8A, solar energy collector system 1100 comprises a photovoltaic-thermal solar energy collector (PVT) 1105 that is capable of collecting heat Q₁ and electrical energy Wₑ. FIG. 8A provides an illustration of the flow of electrical energy and heat through system 1100 during operation. At least a portion of heat Q₁ is transferred to hot reservoir 1115. In some modes of operation, essentially all of heat Q₁ collected by PVT 1105 is transferred to the hot reservoir 1115, and in other modes of operation, at least a portion of heat Q₁ is diverted for a use other than transfer to hot reservoir 1115. Heat pump 1110, which is configured to be powered at least in part using Wₑ from PVT 1105, extracts heat Q₄ from cold reservoir 1120, thereby lowering the temperature of the cold reservoir 1120, and rejects heat Q₅. Heat Q₅ may be rejected to the environment or may be utilized for any suitable use. Heat engine 1125 accepts heat Q₂ from the hot reservoir 1115, rejects heat Q₃ to the cold reservoir 1120, and generates useful work Wᵢₙ. In some cases, useful work Wₒᵤₜ is electrical work. As illustrated in FIG. 8A by arrow 1140, some or all of Wₑ generated by the photovoltaic-thermal solar energy collector 1105 may at certain times during operation be diverted for purposes other than powering heat pump 1110. For example, at certain times during operation, some or all of Wₑ may be delivered to the grid. Although not illustrated in FIG. 8A, at times during operation of system 1100, a portion of heat Q₁ may be diverted for purposes other than transferring heat to hot reservoir 1115.

FIG. 8B provides more detailed coolant flow through system 1100 for which heat and electrical energy flow are illustrated in FIG. 8A. Coolant flow is labeled with a dot over an “M” to indicate the time derivative of mass, i.e., mass flows \dot{M}₁, \dot{M}₂, \dot{M}₃, and so forth. In the variation shown in FIG. 8B, when solar energy is available, the PVT 1105 provides thermal energy Q₁ which is transferred to the hot reservoir 1115 via a flow of heat transfer fluid \dot{M}₁. In the particular example shown in FIG. 8B, heat Q₁ is transferred to heat transfer fluid flow \dot{M}₁ via heat exchanger 1106. In other variations, heat transfer fluid flow \dot{M}₁ is directly heated by the PVT 1105. Also when solar energy is available, PVT 1105 provides electrical energy Wₑ, at least a portion of which may be used operate heat pump 1110. As shown by arrow 1140, at certain times during operation, all or a portion of Wₑ generated by PVT 1105 may be diverted for uses other than powering heat pump 1110. For example, at certain times during operation, some or all of Wₑ may be supplied to the grid. Heat pump 1110 removes heat from a flow of heat transfer fluid \dot{M}₄ drawn from the cold reservoir 120 via heat exchanger 1109, rejects heat Q₅, and delivers a flow of cooled heat transfer fluid \dot{M}₄ to lower the temperature of the cold reservoir 1120. Energy may be stored in the hot and cold reservoirs so that whether or not solar energy is available, a heat engine 1125 may transfer heat from a flow of heat transfer fluid flow \dot{M}₂ drawn from hot reservoir 1115 to a lower temperature flow of heat transfer fluid \dot{M}₃ drawn from cold reservoir 1120 via heat exchangers 1107 and 1108, thereby generating useful work Wᵢₙ. In some variations, Wₒᵤₜ is electrical energy. Because the heat pump 1110 (which is configured to be powered at least in part by electrical energy Wₑ) extracts heat from a cooling loop used by the heat engine 1125, thereby reducing the temperature of the cooling loop, the efficiency of the heat engine 1125 is increased. In some cases, the heat transfer fluid stored in hot reservoir 1115 may be vertically stratified or partially stratified according to temperature (illustrated by dashed line in hot reservoir 1115), with higher temperature fluid residing above lower temperature fluid. In such cases, heat transfer fluid provided from the hot reservoir 1115 to the heat engine 1125 may be preferably drawn from the upper higher temperature strata, as shown. In some cases, the heat transfer fluid stored in cold reservoir 1120 may be vertically stratified or partially stratified by temperature, illustrated by a dashed line in cold reservoir 1120, with cooler fluid residing below hotter fluid. In such cases, heat transfer fluid provided from the cold reservoir 1120 to the heat engine 1125 may be preferably drawn from lower temperature strata, as shown. Heat transfer fluid flow cycles from the heat exchanger 1106 or PVT 1105 through the hot reservoir 1115, from the heat pump 1110 and heat exchanger 1109 through the cold reservoir 1120, and through the heat engine 1125 may each operate independently from each other.

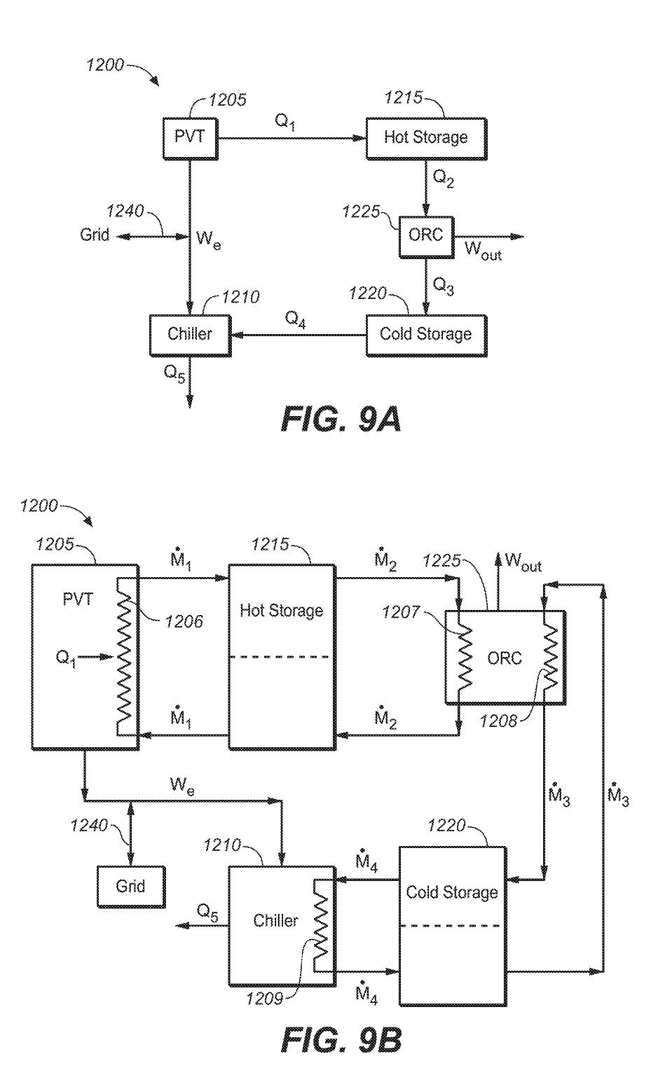

FIG. 9A provides a variation of the solar energy collector system illustrated in FIG. 8A, where the heat pump is a chiller that in operation is used to reduce the temperature of the cold reservoir, and the heat engine is an organic Rankine cycle (ORC) heat engine. FIG. 9A provides an illustration of the flow of electrical energy and heat through system 1200. Here, solar energy collector system 1200 comprises a photovoltaic-thermal solar energy collector (PVT) 1205 that is capable of collecting heat Q₁ and electrical energy Wₑ. At least a portion of heat Q₁ is transferred to hot reservoir 1215. In some modes of operation, essentially all of heat Q₁ is transferred to hot reservoir 1215, and in other modes of operation, at least some of heat Q₁ is diverted for a use other than transfer to hot reservoir 1215. Chiller 1210, which is configured to be powered at least in part using Wₑ from photovoltaic-thermal solar energy collector 1205, extracts heat Q₄ from cold reservoir 1220, thereby lowering the temperature of the cold reservoir 1220, and rejects heat Q₅. Heat Q₅ may be rejected to the environment or may be utilized for any suitable use. Organic Rankine cycle heat engine 1225 accepts heat Q₂ from the hot reservoir 1215, rejects heat Q₃ to the cold reservoir 1220, and outputs useful work Wᵢₙ. In some cases, useful work Wₒᵤₜ is electrical work. As illustrated in FIG. 9A by arrow 1240, some or all of Wₑ generated by the photovoltaic-thermal solar energy collector 1205 may at times during operation be diverted for purposes other than powering heat pump 1210. For example, at certain times during operation, some or all of Wₑ may be delivered to the grid. Although not illustrated in FIG. 9A, at times during operation a portion of heat Q₁ may be diverted for purposes other than transferring heat to hot reservoir 1215.

FIG. 9B provides coolant flow through system 1200 in more detail. In the variation shown in FIG. 9B, when solar energy is available, the PVT 205 collects thermal energy Q₁ which is transferred to the hot reservoir 1215 via a flow of heat transfer fluid \dot{M}₁. In the particular example shown in FIG. 9B, heat Q₁ is transferred to heat transfer fluid \dot{M}₁ via heat exchanger 1206. In other variations, the flow of heat transfer fluid \dot{M}₁ is directly heated by PVT 1205. Also when solar energy is available, PVT 1205 provides electrical energy Wₑ, at least a portion of which may be used operate chiller 1210. As shown by arrow 1240, at certain times during operation all or a portion of Wₑ generated by PVT 1205 may be diverted for uses other than powering chiller 1210. For example, at certain times a portion or all of Wₑ may be supplied to the grid. Chiller 1210 removes heat from a flow of heat transfer fluid \dot{M}₄ drawn from the cold reservoir 1220 via heat exchanger 1209, rejects heat Q₅, and delivers a flow of cooled heat transfer fluid \dot{M}₄ to lower the temperature of the cold reservoir 1220. Whether or not solar energy is available, an organic Rankine cycle heat engine (ORC) 1225 may transfer heat from a flow of heat transfer fluid flow \dot{M}₂ drawn from hot reservoir 1215 to a lower temperature flow of heat transfer fluid \dot{M}₃ drawn from cold reservoir 1220 via heat exchangers 1207 and 1208, thereby generating useful work Wₒᵤₜ, which may be electrical energy. Because the chiller 1210 (which is configured to powered at least in part by electrical energy generated by the PVT 1205) extracts heat from a cooling loop used by the ORC 1225, thereby reducing the temperature of the cooling loop, the efficiency of the

ORC 1225 is increased. In some cases, the heat transfer fluid stored in hot reservoir 1215 may be vertically stratified or partially stratified according to temperature (illustrated by dashed line in hot reservoir 1215), with higher temperature fluid residing above lower temperature fluid. In such cases, heat transfer fluid provided from the hot reservoir 1215 to the ORC 1225 may be preferably drawn from the upper higher temperature strata, as shown. In some cases, the heat transfer fluid stored in cold reservoir 1220 may be vertically stratified or partially stratified by temperature, illustrated by a dashed line in cold reservoir 1220, with cooler fluid residing below hotter fluid. In such cases, heat transfer fluid provided from the cold reservoir 1220 to ORC 1225 may be preferably drawn from lower temperature strata, as shown. Heat transfer fluid flow cycles from the heat exchanger 1206 or PVT 1205 through the hot reservoir 1215, from the heat pump 1210 and heat exchanger 1209 through the cold reservoir 1220, and through the ORC 1225 may each operate independently from each other.

In some variations of the systems and methods of FIGS. 8A-12, one or more components are common to both the heat pump and the heat engine, where a common component has a certain function during a chilling cycle when the common component is used by the heat pump and a different function during a work generating cycle when the common component is used by the heat engine to generate work. In some cases, the heat pump and the heat engine utilizing one or more common components are integrated into a single unit. The use of one or more common components by the heat pump and heat engine is enabled because in certain operational modes for the systems and methods described herein, the heat engine and the heat pump or chiller are not generally operated at the same time.

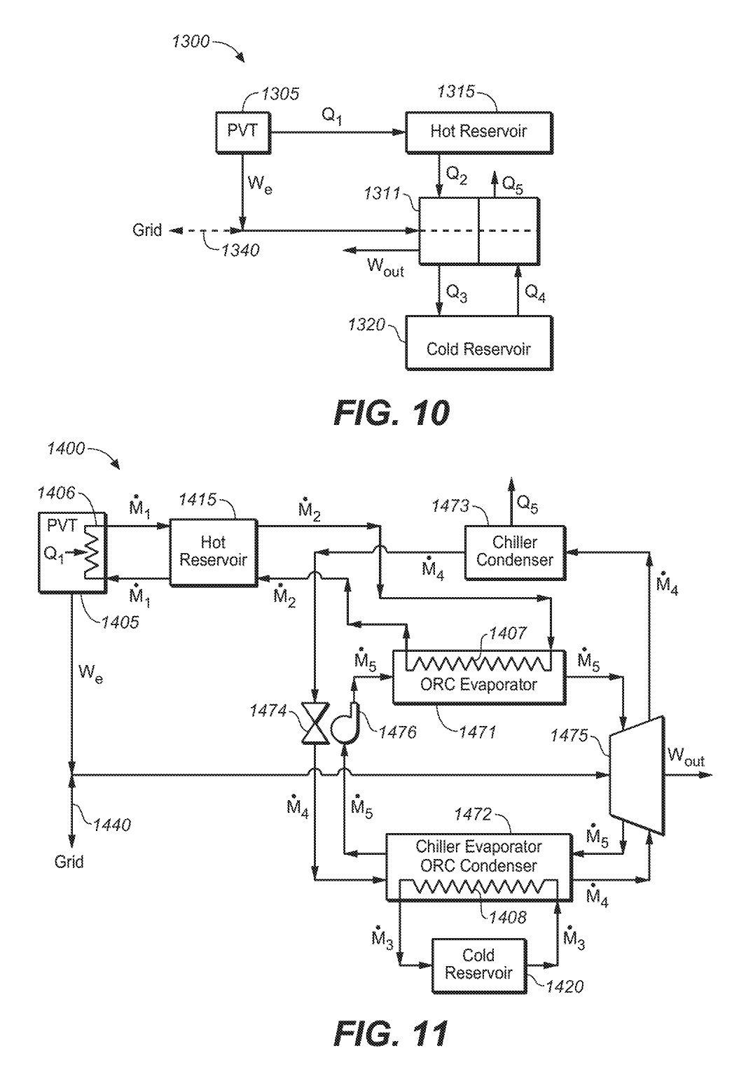

An example of a system in which one or more components are common to both the heat pump and the heat engine is illustrated in FIG. 10. The system illustrated in FIG. 10 may be operated in two distinct cycles: a) a chilling cycle, in which the heat pump or chiller is operating to lower to the temperature of the cold reservoir; and b) a work generating cycle, in which the heat engine (e.g., ORC) is operating between the cold reservoir and the hot reservoir to generate useful work. Referring now to FIG. 10, solar energy collector system 1300 comprises a photovoltaic-thermal solar energy collector 1305 which collects heat Q₁ and electrical work Wₑ. At least a portion of heat Q₁ is transferred to a hot reservoir 1315. In some modes of operation, essentially all of heat Q₁ collected by PVT 1305 is transferred to hot reservoir 1315, and in other modes of operation, at least a portion of heat Q₁ is diverted for a use other than transfer to hot reservoir 1315. A combined heat engine/heat pump 1311 is configured to be powered at least in part with Wₑ. The combined heat engine/heat pump has one or more components that are common to both a heat pump and a heat engine in a system as described herein. The combined heat engine/heat pump may or may not be assembled as an integrated unit. Although one or more components of the combined heat engine/heat pump have a dual function (i.e., function in one manner for the chilling cycle and function in another manner for the work generating cycle), other components of the combined heat engine may have a use specific to the heat pump functionality, or a use specific to the heat engine functionality. As indicated by arrow 1340, at certain times during operation, all or a portion of Wₑ may be delivered to the grid, for example to supply electricity at a time when the electrical energy has increased monetary value. When operating in a chilling mode, a chiller/heat pump apparatus in the combined heat engine/heat pump 1311 removes heat Q₄ from a cold reservoir 1320 and rejects heat Q₅, thereby lowering the temperature of the cold reservoir 1320. When operating in a work generating mode, a heat engine (e.g., ORC heat engine) apparatus in the combined heat engine/heat pump 1311 operates to accept heat Q₂ from the hot reservoir 1315, reject heat Q₃ to the cold reservoir 1320, and to provide as output useful work Wₒᵤₜ, which may be electrical work.

A more detailed example of a system in which the heat engine and heat pump share one or more common components is provided in FIG. 11. System 1400 illustrated in FIG. 11 may be operated in two distinct cycles: a) a chilling cycle, in which the heat pump or chiller is operating to lower to the temperature of the cold reservoir; and b) a work generating cycle, in which the ORC is operating between the cold reservoir and the hot reservoir to generate useful work. System 1400 comprises the following components that have dual functionality and differ in function between the chilling cycle and the work generating cycle: a chiller evaporator/ORC condenser 1472 that functions as an ORC condenser (heat sink) during the work generating cycle and functions as a chiller evaporator (heat source) during the chilling cycle; and an ORC turbine/compressor 1475 that functions as a turbine during the work generating cycle and functions as a chiller compressor during the chilling cycle. The ORC turbine may be operated in reverse so that it changes operation from expanding gas to compressing gas. System 400 includes the following components that have functions specific to the chilling or work generating cycles: a pump 1476 that operates during the work generating cycle but is replaced by an expansion valve 1474 that operates during the chilling cycle; and an ORC evaporator (heat source) 1471 that operates during the work generating cycle but is replaced by a chiller condenser (heat sink) 1473 that operates during the chilling cycle. Although not explicitly shown in FIG. 11, system 1400 may include one or more valves which may be operated to switch operation from a chilling cycle to a work generating cycle.

During operation of system 1400, photovoltaic-thermal solar energy collector 1405 collects heat Q₁ and generates electrical energy Wₑ. At least a portion of heat Q₁ is transferred to hot reservoir 1415. In some modes of operation, essentially all of heat Q₁ is transferred to hot reservoir 1415. In other modes of operation, at least a portion of heat Q₁ is diverted for a use other than transfer to hot reservoir 1415.

A description of the operation of system 1400 during the chilling cycle follows. Compressor 1475 may be configured to be powered at least in part using Wₑ during the chilling cycle. In some modes of operation, the compressor 1475 is powered entirely by Wₑ, and in some modes of operation an external energy source e₃ (e.g., electricity from the grid, as indicated by arrow 1440) may be used alone or in combination with Wₑ to power compressor 1475. A cooling loop (working fluid flow \dot{M}₄) passes from the chiller compressor 1475 to the chiller condenser 1473, from the chiller condenser 1473 to the throttling or expansion valve 1474, from the expansion valve 1474 to the chiller evaporator 1472, which is in thermal communication with cold reservoir 1420 via heat exchanger 1408, and from the chiller evaporator 1472 back to the compressor 1475. During the chilling cycle, chiller compressor 1475 accepts gas flow \dot{M}₄ from the chiller evaporator 1472 and supplies compressed gas flow \dot{M}₄ to the chiller condenser 1473. Chiller condenser 1473 accepts compressed gas flow \dot{M}₄ from compressor 1475, removes heat from flow \dot{M}₄, rejects heat Q₅ and supplies condensed liquid flow \dot{M}₄ to expansion valve 1474. The chiller condenser 1473 operates by heat exchange and rejects heat in any suitable manner, for example, rejecting heat to air or to liquid (e.g., water). Expansion valve 1474 accepts liquid flow \dot{M}₄ and expands the working fluid to result, typically, in a mixture of liquid and gas. Operation of throttling or expansion valve 1474 is typically isenthalpic. Gas/liquid flow \dot{M}₄ from the expansion valve 1474 is supplied to chiller evaporator 1472, where any remaining liquid in flow \dot{M}₄ is vaporized. In this vaporization step, heat is drawn out of the cold reservoir 1420 by working fluid flow \dot{M}₃ via heat exchanger 408, thereby cooling cold reservoir 1420. Gas flow \dot{M}₄ from the chiller evaporator 1472 is returned to compressor 1475 to continue the cooling cycle.

A description of the operation of system 1400 during the work generating cycle follows. During the work generating cycle, at least a portion of Wₑ may be diverted to the grid, as indicated by arrow 1440, or used for a purpose other than powering compressor 1475. A work generating loop (working fluid flow \dot{M}₅) passes from the pump 1476 to the ORC evaporator 1471, from the ORC evaporator 1471 (which is in thermal communication with the hot reservoir 1415 via heat exchanger 1407) to the ORC turbine 1475, from the turbine 1 475 to the ORC condenser 1472 (which is in thermal communication with cold reservoir 1420 via heat exchanger 408), and from the ORC condenser 1472 back to the pump 1476. In some modes of operation, the pump 1476 is powered entirely by Wₑ, and in some modes of operation an external energy source e₃ (e.g., electricity from the grid, as indicated by arrow 1440) may be used alone or in combination with Wₑ to power pump 1476. Pump 1476 pumps liquid fluid \dot{M}₅ to ORC evaporator 1471. Heat from fluid \dot{M}₂ from the hot reservoir 1415 is transferred to fluid \dot{M}₅ via heat exchanger 1407 in the ORC evaporator 1471, vaporizing fluid \dot{M}₅. The heated vaporized fluid \dot{M}₅ from ORC evaporator 1471 is expanded in ORC turbine 1475 to drive the turbine and generate useful work Wₒᵤₜ, which may be electrical work. Expanded gas flow \dot{M}₅ from turbine 1475 enters ORC condenser 1472, where fluid \dot{M}₅ is cooled and condensed via heat exchange with working fluid \dot{M}₃ from cold reservoir 1420. Condensed liquid flow \dot{M}₅ exits ORC condenser 1472 and returns to pump 1476.

For the systems and methods of FIGS. 8A-12, a ratio of collected heat Q₁ to electrical energy Wₑ produced by a photovoltaic-thermal solar energy collector may be varied. In some cases, a ratio Q₁:Wₑ is about 1, about 2, about 3, about 4, about 5, about 6, about 7, about 8, about 9 or about 10. In some variations, a ratio Q₁:Wₑ is about 4.

The solar energy systems and methods of FIGS. 8A-12 may in operation store energy in the hot and cold reservoirs. The heat engine may be operated at a time delayed relative to the generation of electrical energy Wₑ to generate dispatchable useful work, e. g., dispatchable electrical energy. The dispatchable useful work may be produced as demanded, for example, during low solar output times, or during high demand periods. In some variations, the systems or methods may be operated to generate an amount of dispatchable electrical energy that is at least 0.5 times the solar-generated electrical energy Wₑ, at least 0.6 times Wₑ, at least 0.7 times Wₑ, at least 0.8 times Wₑ, or at least 0.9 times Wₑ. In some modes of operation, the systems or methods may generate an amount of dispatchable electrical energy that is about equal to the solar-generated electrical energy Wₑ. During some modes of operation, some systems or methods may generate an amount of dispatchable electrical energy that is greater than the solar-generated electrical energy Wₑ.

For the systems and methods of FIGS. 8A-12, any suitable type of heat engine may be used. Non-limiting examples of suitable heat engines include Rankine cycle heat engines (e. g., organic Rankine cycle (ORC) heat engines), Brayton cycle heat engines, and Stirling cycle heat engines. Other non-limiting examples of heat engines include any type of thermoelectric device or thermoelectric generator that is capable of converting heat to electrical energy. In some cases, an organic Rankine cycle heat engine is used. The temperatures of the hot and cold reservoirs may be selected so that during operation the heat engine (e.g., an ORC heat engine) has an efficiency of at least about 12%, at least about 12.5%, at least about 13%, at least about 13.5%, at least about 14%, at least about 14.5%, at least about 15%, at least about 15.5%, at least about 16%, at least about 16.5%, at least about 17%, at least about 17.5%, at least about 18%, at least about 18.5%, or at least about 19%.

For the systems and methods of FIGS. 8A-12, any suitable type of chiller may be used. In some cases, the chiller has a COP of about 3 or greater, about 4 or greater, about 5 or greater, or about 6 or greater. In some variations, the chiller has a COP in a range from about 4 to about 10, about 4 to about 8, about 4 to about 7, about 5 to about 10, about 5 to about 8, about 5 to about 7, from about 6 to about 10, about 6 to about 8, or about 6 to about 7. As described above, non-limiting examples of chiller types include vapor-compression chillers, air chillers, absorption chillers, adsorption chillers, and reverse Stirling engine chillers. Chillers may be air-cooled or water-cooled. The chiller used may exhaust to any suitable heat sink, for example, exhaust to air or exhaust to a reservoir of water. Non-limiting examples of chillers that may be used include a YK Water-Cooled Centrifugal Chiller, and a YVAA Air-Cooled Variable Speed Screw Chiller, each available from YORK® Chillers (Johnson Controls, Incorporated, Milwaukee, Wis.).

Any suitable type of hot and cold reservoirs may be used in the systems and methods of FIGS. 8A-12. The hot reservoir may comprise a vessel containing a thermal energy storage medium (for example, water). The cold reservoir may comprise a vessel containing a thermal energy storage medium (for example, water, ice, or a mixture of water and ice) from which heat may be drawn. In some variations, the heated thermal energy storage medium in the hot reservoir and/or the cooled thermal energy storage medium may be used for one or more applications other than operating the heat engine. For example, the cooled thermal energy storage medium may be used for one or more cooling applications, which may be internal or external to the system. In some cases, cooled working fluid from the cold reservoir may be used to cool one or more photovoltaic cells to increase their efficiency to a desired level.

In general, the temperature difference between the hot and cold reservoirs affects the efficiency of the heat engine that is used to convert the energy stored between the hot and cold reservoirs to useful work. Also, an efficiency of photovoltaic cells in the photovoltaic-thermal solar energy collector decreases with increasing temperature. An efficiency of the heat pump drawing heat from the cold reservoir decreases as the temperature of the cold reservoir is lowered. The operating temperature of the hot reservoir and the cold reservoir may be selected to strike a desired trade-off between energy consumption of the heat pump, efficiency of photovoltaic cells, and efficiency of the heat engine. In general, the cost of storing energy in the hot and cold reservoirs is very low, unlike battery-based or electrochemical energy storage schemes. Further, the temperature of the hot and cold reservoirs can be cycled indefinitely with no degradation in performance, and without the use of chemicals, unlike battery-based or electrochemical energy storage schemes.

In the systems and methods of FIGS. 8A-12, the photovoltaic-thermal solar energy collector may be operated at any suitable temperature. In some cases, the photovoltaic-thermal solar energy collector is operated at a temperature of about 100° C.-120° C., or about 110° C.-120° C. In those cases, photovoltaic cells in the photovoltaic-thermal solar energy collector may be selected that have useful efficiencies at an operating temperature of about 120° C. For example, the photovoltaic-thermal solar energy collector may comprise one or more heterojunction intrinsic thin film photovoltaic cells capable of generating electrical energy at an operating temperature of about 120° C.

During operation of the systems and methods of FIGS. 8A-12, the hot reservoir may be heated and the cold reservoir may be cooled to achieve a desired temperature difference between the hot reservoir and the cold reservoir so that the heat engine operating between the hot and cold reservoir operates with a desired efficiency. The temperature of the cold reservoir may be cooled to a temperature T_{L}, where T_{L} is selected to optimize energy stored in the hot and cold reservoirs from which dispatchable energy is produced by operation of the heat engine. In certain systems and methods utilizing an organic Rankine cycle heat engine, the hot reservoir may be heated to a temperature of about 110° C.-120° C. (e.g., about 110° C., about 115° C., or about 120° C.) and the cold reservoir may be cooled to a temperature of about −5° C. to about 10° C., e.g., about −5° C., about −3° C., about −2° C., about −1° C., about 0° C., about 1° C., about 2° C., about 3° C., about 5° C., about 6° C., about 7° C., about 8° C., about 9° C., or about 10° C. In some systems or methods employing an organic Rankine cycle heat engine, hot water may be stored in the hot reservoir at a temperature of about 120° C. and cold water may be stored in the cold reservoir at a temperature T_{L} that is in a range from about −5° C. to about 10° C., or from about −3° C. to about 7° C., or from about 0° C. to about 7° C., or from about 0° C. to about 5° C. For example the temperature of the hot reservoir may be about 120° C. and T_{L} may be about −3° C., about −2° C., about −1° C., about 0° C., about 1° C., about 2° C., about 3° C., about 4° C., about 5° C., about 6° C., or about 7° C.

In certain operational modes of the systems and methods of FIGS. 8A-12, the heat pump or chiller is not operated at the same time as the heat engine. At peak power demand times which typically occur in the afternoon, it may be economically beneficial to sell Wₑ generated by the PVT to the grid rather than to use it for cooling the cold reservoir. The periods during which the heat pump or chiller is operated to cool the cold reservoir may be selected based on efficiency and economic considerations and/or on ambient considerations. In some operational modes, the heat pump or chiller may be operated while Wₑ is being generated. In some operational modes, it may be beneficial to run the chiller during periods in which power is relatively inexpensive, e.g., at night or on weekends, taking into account seasonal and random signal power metering. The chiller may be operated when the ambient temperature is lower, e.g., at night, in the morning, or during low solar radiation periods.

Certain operating modes of the systems or methods of FIGS. 8A-12 may comprise using substantially all of electrical energy Wₑ to drive the heat pump. In other operational modes, all or a portion of Wₑ may be diverted (e.g., for another use internal or external to the system, or to be supplied and sold to the grid). For example, in certain modes of operation, a portion of Wₑ may be used to drive the heat pump, and a portion (e.g., the balance of Wₑ that is not used to drive the heat pump) may be supplied and sold to the grid.

Certain variations of the systems and methods of FIGS. 8A-12 may comprise or employ a controller configured for controlling a portion of photovoltaic electrical energy Wₑ that is used to power the heat pump or chiller and a portion of electrical energy Wₑ that is supplied and sold to an electrical grid during operation, based on a time-dependent market value of electricity.

The systems and methods of FIGS. 8A-12 may employ a variety of schemes by which the heat pump or chiller is driven at least in part using electrical energy Wₑ generated by the PVT. In some operational modes, substantially all of the electrical energy Wₑ is used to drive the heat pump. In other operational modes, a portion of Wₑ is diverted for one or more other applications (which may be internal or external to the system), or to be sold to an electric power grid. In certain variations, external energy e₃ from an external energy source is used to drive the heat pump. Although the heat pump is configured to powered at least in part using We generated by the PVT, there may be periods during operation in which the heat pump is powered using an external energy source e₃. For example, it may be beneficial or more efficient to operate the heat pump during the night when the ambient temperature is cooler to lower the temperature of the cold reservoir, and to use power from the grid to drive the heat pump. External energy e₃ need not be from the grid, and any type of energy may be used, including energy derived from burning fossil fuels or plant-based fuels, from a generator, from another solar energy collector, from a wind turbine, from a battery, from a hydroelectric source, or the like. When external energy e₃ is used in combination with Wₑ to drive the heat pump or chiller, e₃ and Wₑ may be used in any suitable relative amounts. For example, electrical energy Wₑ and e₃ may be used to drive the heat pump or chiller where Wₑ and e₃ are used in a ratio Wₑ:e₃ of about 1:1000, about 1:800, about 1:500, about 1:200, about 1:100, about 1:50, about 1:20, about 1:10, about 1:5, about 1:3, about 1:2, about 1:1, about 2:1, about 3:1, about 5:1, about 10:1, about 20:1, about 50:1, about 100:1, about 200:1, about 500:1, about 800:1, or about 1000:1. When external energy source e₃ and Wₑ are used in combination to drive the heat pump, the energy sources may be combined in any suitable manner. For example, Wₑ and e₃ may be used in a parallel operation so that both Wₑ and e₃ are supplied simultaneously to the heat pump in any relative amounts. The relative amounts of Wₑ and e₃ need not stay constant with time, and may be adjusted according to operating conditions (e.g., time of day, weather, season and/or demand). In other operating modes, Wₑ and e₃ may be alternately supplied to drive the heat pump, so that when Wₑ is supplied, e₃ is not supplied, and when e₃ is supplied We is not supplied. Any suitable scheme for alternating Wₑ and e₃ may be used. The alternating may occur at regular intervals or irregular internal (e.g., irregular intervals determined by an operator or controller based on operating conditions or demand). If Wₑ and e₃ are alternated at regular intervals, the frequency ate which they are alternated may be any suitable frequency, and the frequency of alternating may be constant or non-constant (e.g., adjusted during operation to accommodate operating conditions such as time of day, weather, season and/or demand). For example, Wₑ may be used to drive the heat pump during sunlight hours and e₃ may be used to drive the heat pump during darkness or cloud cover. Durations of alternating intervals may be adjusted, for example, seasonally.

In the systems and methods of FIGS. 8A-12, at least a portion of solar-generated heat Q₁ is used to heat the hot reservoir, but it is not required that all of heat Q₁ be used to heat the hot reservoir. In some variations, substantially all of heat Q₁ is used to heat the hot reservoir, and in other variations, a portion of heat Q₁ is diverted for a use other than heating the hot reservoir. In some variations, the systems or methods may employ a supplemental heat source to heat the hot reservoir.

A photovoltaic-thermal solar energy collector collects heat (Q₁) and generates photovoltaic electrical energy (Wₑ). During operation, it is advantageous to determine an optimal amount of photovoltaic energy Wₑ to use to cool the cold reservoir. It is desired to cool the cold reservoir sufficiently to increase the efficiency of the heat engine (e.g., ORC) to optimize electrical output without cooling unnecessarily. Photovoltaic electricity Wₑ that is not used to power a chiller to cool the cold reservoir can be supplied to the grid, or put to another valuable use. Heat pump/chillers become less efficient as operating temperature is decreased, so that increasing amounts of energy are required to cool to lower temperatures. At some cooling temperature, the benefit to the ORC efficiency of cooling further does not outweigh the cost of the extra energy needed to power the heat pump/chiller. One method for determining an optimal amount of energy storage given a certain heat (Q₁) to photovoltaic electrical energy (Wₑ) ratio is described here. R is defined as the ratio of the outputs Q₁/ Wₑ. The temperature of the low temperature (cold) side of the chiller is T_{L}, which can be used as the chiller cooling set point. Eff(T_{L}) is the efficiency of the ORC as a function of T_{L}. Ch(T_{L}) is the COP of the chiller as a function of T_{L}. The efficiency of the ORC Eff(T_{L}) increases as T_{L} decreases, and as a secondary effect, less heat is rejected. The efficiency of the chiller Ch(T_{L}) decreases as T_{L} decreases. Eₒᵤₜ(T_{L}) is the amount of electrical energy (relative to electrical energy used to power the chiller) that can be generated from the hot and cold reservoirs as a function of T_{L}, and is calculated as: Eₒᵤₜ(T_{L})=R×Eff(T_{L}). Ch(T_{L}) provides the amount of energy (relative to the electrical energy used to power the chiller) that is stored in the cold reservoir. To optimize Eₒᵤₜ(T_{L}), T_{L} may be selected to balance between increasing efficiency of the ORC and decreasing efficiency of the chiller as the set point temperature T_{L} is lowered. T_{L} may be selected so that Ch(T_{L})=R×[1−Eff(T_{L})]. The excess cooling can be calculated as {Ch(T_{L})−[R×(1−Eff(T_{L}))]}. For one non-limiting example, assume R=4/1 for a representative PVT, T_{L}=5° C., Ch(T_{L})=4 for a representative chiller, and Eff(T_{L})=0.125 for a representative ORC, then the excess cooling is calculated as {4−[4×(1−0.125)]}=0.5. The corresponding non-optimized electrical output from the ORC is Eₒᵤₜ(T_{L})=4×0.125=0.5. For another non-limiting example, assuming R=4/1 for a representative PVT, T_{L}=0° C., Ch(T_{L})=3.333 for a representative chiller and Eff(T_{L})=0.166 for a representative ORC, then the excess cooling is calculated as {3.333−[4×(1−0.166)]}=0. The corresponding optimized electrical output from the ORC is Eₒᵤₜ(T_{L})=433 0.166=0.667. Optionally, analytic equations describing the function of the chiller COP as a function of T_{L} and the ORC efficiency as a function of T_{L} may be used to find a temperature T_{L} that does not result in excess cooling and optimizes Eₒᵤₜ(T_{L}).

In one non-limiting prophetic example, a photovoltaic-thermal solar energy collector is capable of generating 1 kWh electrical energy and collects 4 kWh thermal energy. The PVT operates at about 120° C., so that the hot reservoir has a hot storage temperature of about 120° C. Referring again to FIGS. 9A-9B, heat transfer fluid flow \dot{M}₂ having a temperature of about 120° C. flows from the hot reservoir 1215 through a heat exchanger 1207 and exits the heat exchanger at about 110° C., so there is an approximate 10° C. temperature drop across the heat exchanger 1207 to the ORC 1225 (e.g., an evaporator of the ORC). The cold reservoir 1220 is cooled so that T_{L} is about 7° C. Heat transfer fluid flow \dot{M}₃ having a temperature of about 7° C. flows from cold reservoir 1220 through heat exchanger 1208 and exits the heat exchanger at about 12° C., so there is about a 5° C. temperature increase across the heat exchanger 1208 to the ORC (e.g., a condenser of the ORC). When T_{L}=7° C., the ORC has an efficiency of about 13.5% (which is about 50% of a theoretical maximum efficiency). When T_{L}=7° C., the chiller has a COP of about 6.4 (i.e., for one unit of electrical energy supplied to the chiller, 6.4 units of heat are removed from the cold reservoir), which is about 35% of theoretical maximum COP. If 0.46 kWh of the 1 kWh electrical energy is supplied to the grid and 0.54 kWh of the 1 kWh electrical energy produced is used to power the chiller, then this 0.54 kWh is effectively stored in the cold reservoir. The 0.54 kWh effectively stored by cooling the cold reservoir, together with the 4 kWh heat stored in the hot reservoir are converted into electrical work by the ORC having an efficiency of 0.135. The amount of electrical energy generated by the ORC is 4 kWh×0.135=0.54 kWh. An electrical efficiency, or conversion efficiency, can be calculated, which is a ratio of the total amount of electrical energy produced by the ORC to the total amount of electrical energy effectively stored in cold reservoir, which in this case is about 100%, i.e., essentially all the electrical energy that is effectively stored by cooling the cold reservoir is converted to useful electrical energy. The marginal benefit associated with effectively storing the photovoltaic energy by cooling the cold reservoir instead of running the ORC between the hot reservoir and a non-cooled reservoir at or near ambient temperature for this example is about 0.35. That is, for every 1 kWh of photovoltaic electric energy, 0.35 kWh additional energy is effectively stored by cooling the reservoir.

In another non-limiting prophetic example, a photovoltaic-thermal solar energy collector is capable of generating 1 kWh electrical energy and collects 4 kWh thermal energy. The PVT operates at about 120° C., so that the hot reservoir has a hot storage temperature of about 120° C. Referring again to FIGS. 9A-9B, heat transfer fluid flow \dot{M}₂ having a temperature of about 120° C. flows from the hot reservoir 1215 through a heat exchanger 1207 and exits the heat exchanger at about 110° C., resulting in an approximate 10° C. temperature drop across the heat exchanger 1207 to the ORC 1225 (e.g., an evaporator of the ORC). The cold reservoir 1220 is cooled so that T_{L} is about 0° C. Heat transfer fluid flow \dot{M}₃ having a temperature of about 0° C. flows from cold reservoir 1220 through heat exchanger 1208 and exits the heat exchanger at about 5° C., so there is about a 5° C. temperature increase across the heat exchanger 1208 to the ORC (e.g., a condenser of the ORC). When T_{L}=0° C., the ORC has an efficiency of about 18.7% (which is about 60% of a theoretical maximum efficiency). When T_{L}=0° C., the chiller has a COP of about 6.45 (i.e., for one unit of electrical energy supplied to the chiller, 6.45 units of heat are removed from the cold reservoir), which is about 50% of theoretical maximum COP. If 0.49 kWh of the 1 kWh electrical energy produced by the PVT 205 is supplied to the grid and 0.51 kWh of the 1 kWh electrical energy produced by the PVT is used to power the chiller, then this 0.51 kWh is effectively stored in the cold reservoir. The 0.51 kWh effectively stored by cooling the cold reservoir, together with the 4 kWh heat stored in the hot reservoir are converted into electrical work by the ORC having an efficiency of 0.187. The amount of electrical energy generated by the ORC is 4 kWh×0.187=0.748 kWh. An electrical efficiency, or conversion efficiency, can be calculated, which is a ratio of the total amount of electrical energy produced by the ORC to the total amount of electrical energy effectively stored in cold reservoir, which in this case is 0.748 kWh/0.51 kWh, or about 147%. In this example, the marginal benefit associated with effectively storing the photovoltaic energy by cooling the cold reservoir instead of running the ORC between the hot reservoir and a non-cooled reservoir at or near ambient temperature for this example is about 0.49.

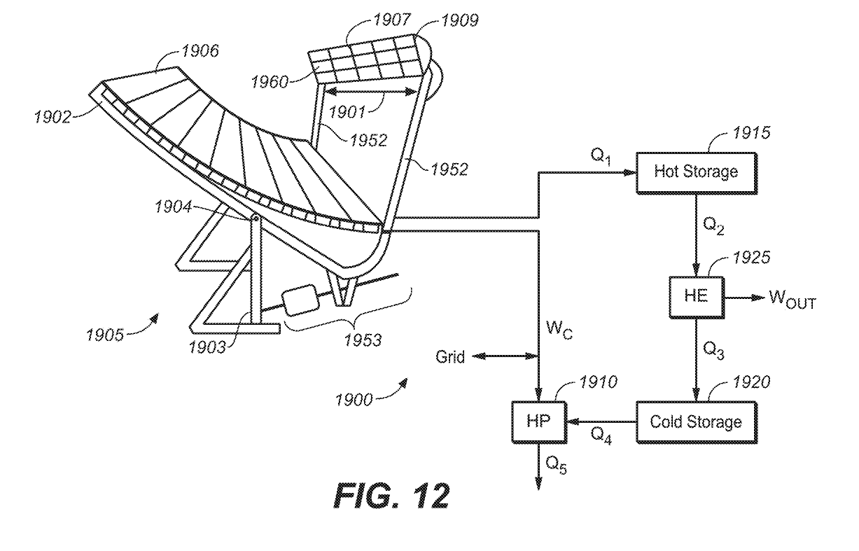

FIG. 12 provides a non-limiting example of a solar energy system comprising a photovoltaic-thermal solar energy collector that collects heat Q₁ and electrical energy We and is configured for storing energy in hot and cold reservoirs, and using a heat engine operating between the hot and cold reservoirs to generate dispatchable useful work, whether or not solar radiation is available. In this example, system 1900 comprises a photovoltaic-thermal solar energy collector 1905, a cold reservoir 1920, a hot reservoir 1915, a heat pump 1910, and a heat engine 1925. The photovoltaic-thermal solar energy collector 1905 comprises a concentrating solar reflector 1906 mounted on a support 1902. The reflected sunlight from reflector 906 is directed towards and focused on receiver 1907 which is mounted on arms 1952 of support 1902. Support 1902 is pivotally coupled to base supports 1903 at pivot points 1904. Rotation about pivot points 1904 enables positioning of the reflector 1906, for example rotation of the reflector for tracking of the sun. Receiver 1907 rotates with reflector 1906 as support 1902 is rotated. Optionally, receiver 1907 may be rotated about pivot points 1909 to optimize collection of the reflected light. Rotation about pivot points 1904 may be accomplished using any suitable mechanism. For example, a linear actuator 1953 coupled to support 1902 may be used to drive rotation about the pivot points 1904 so that reflector 1906 tracks the sun. Alternatively, supports 1902 may be mounted to a rotationally driven torque tube having a rotational axis passing through pivot points 1904. In this particular example, the concentrating reflector 1906 concentrates the reflected sunlight into an approximately linear focus on receiver 1907. The receive 1907 comprises photovoltaic cells (not shown) extending approximately along the length 1901 of the receiver 1907. Heat transfer fluid may be circulated through one or more fluid channels to collect heat. Although a single reflector/receiver/support module is shown in FIG. 12, the photovoltaic-thermal solar energy collector 1905 may comprise multiple reflector/receiver/support modules, which may be arranged in a variety of configurations. For example, a series of multiple reflector/receiver/support modules may be arranged lengthwise (parallel to length 1901) to form a row of modules. In some cases, multiple rows of modules may be arranged to form a solar energy collector. The modules may be coupled together in any manner to collect electrical energy produced by photovoltaic cells and heat collected by heat transfer fluid flowing through the receivers. Any other suitable photovoltaic-thermal solar energy collector may be used in addition to or in place of the particular photovoltaic-thermal solar energy collector illustrated in FIG. 12.

Still referring to FIG. 12, the photovoltaic-thermal solar energy collector 1905 generates electrical energy Wₑ via photovoltaic cells in the receiver 1907 and collects and carries heat Q₁ using a heat transfer fluid circulating through one or more fluid channels in receiver 1907. In operation, at least a portion of heat Q₁ is transferred to the hot reservoir 1915. In operation, heat pump or chiller 1910 draws heat Q₄ from the cold reservoir, thereby reducing its temperature, and rejects heat Q₅. Heat pump or chiller 1910 is configured to be powered at least in part using electrical energy Wₑ. As described herein, in certain modes of operation, all or a portion of Wₑ may be diverted and sold to the grid as indicated by arrow 1940. In some modes of operation, an external energy source e₃ (not shown), or a combination of external energy e₃ and Wₑ is used to drive heat pump 1910. Energy may be stored in the hot and cold reservoirs as long as desired. At a desired time, which may be a time delayed relative to the generation of Wₑ by PVT 1905, heat engine 1925 is operated between the hot and cold reservoirs to generate useful work Wₒᵤₜ. Because energy may be stored inexpensively and efficiently in hot and cold reservoirs, heat engine 1925 generates dispatchable useful work, which may be generated whether or not solar radiation is available at any desired time (e.g., to respond to peak demand, to generate electricity when the value of electricity is high, to supply electricity during darkness or cloud cover, and the like).

This disclosure is illustrative and not limiting. Further modifications will be apparent to one skilled in the art in light of this disclosure and are intended to fall within the scope of the appended claims.

1-46. (canceled)

47. A solar energy system for producing dispatchable electrical energy, the system comprising:
a concentrating photovoltaic-thermal solar energy collector that generates electrical energy e1 and collects thermal energy h1;
a cold reservoir;
a heat pump powered at least in part by electrical energy e1 to draw heat h2 from the cold reservoir;
a hot reservoir heated at least in part with heat h1 and heat h2; and
a heat engine configured to convert thermal energy in the hot reservoir to electrical energy e2.

48-62. (canceled)

63. The system of claim 47, comprising:
a heat transfer fluid HTF1 that, in operation, flows through one or more fluid channels in the photovoltaic-thermal solar energy collector to collect thermal energy h1; and
a heat transfer fluid HTF2 that is heated by the heat pump to carry heat h2.

64. The system of claim 63, comprising a heat exchanger that, in operation, transfers heat between heat transfer fluid HTF1 and heat transfer fluid HTF2.

65. The system of claim 63, wherein heat transfer fluid HTF1 heated by the photovoltaic-thermal solar energy collector has temperature T1 and heat transfer fluid HTF2 heated by the heat pump has temperature T2, and T1 is greater than T2.

66. The system of claim 63, wherein heat transfer fluid HTF1 heated by the photovoltaic-thermal solar energy collector has temperature T1 and a heat transfer fluid HTF2 heated by the heat pump has temperature T2, and T2 is greater than T1.

67. The system of claim 63, wherein heat transfer fluid HTF1 heated by the photovoltaic-thermal solar energy collector has temperature T1 and heat transfer fluid HTF2 heated by the heat pump has temperature T2, and T1 is approximately equal to T2.

68. The system of claim 47, wherein, in operation, a heat transfer fluid HTF2 is heated by the heat pump to carry heat h2 and have a temperature T2 and then passes through one or more fluid channels in the photovoltaic solar thermal energy collector to collect heat h1 and thereby increase its temperature to a temperature T2′ greater than T2.

69-79. (canceled)

80. A method for generating dispatchable electrical energy, the method comprising:
generating electrical energy e1 and collecting heat h1 using a concentrating photovoltaic-thermal solar energy collector;
drawing heat h2 from a cold reservoir using a heat pump powered at least in part by electrical energy e1;
heating a hot reservoir at least in part using heat h1 and heat h2; and
generating electrical energy e2 using thermal energy in the hot reservoir.

81-95. (canceled)

96. The method of claim 80, comprising:
flowing a heat transfer fluid HTF1 through one or more fluid channels in the photovoltaic-thermal energy solar collector to collect thermal energy h1; and
transferring heat h1 carried by heat transfer fluid HTF1 to a heat transfer fluid HTF3 via heat exchange; and
heating the reservoir with heat transfer fluid HTF3 carrying heat h1.

97. The method of claim 80, comprising:
flowing a heat transfer fluid HTF1 through one or more fluid channels in the photovoltaic-thermal energy solar collector to collect heat h1; and
using a heat transfer fluid HTF2 to collect heat h2 from the heat pump.

98. The method of claim 97, comprising using a heat exchanger to transfer heat between heat transfer fluid HTF1 and heat transfer fluid HTF2.

99. The method of claim 97, wherein heat transfer fluid HTF1 heated by the photovoltaic-thermal solar energy collector has temperature T1 and heat transfer fluid HTF2 heated by the heat pump has temperature T2, and T1 is greater than T2.

100. The method of claim 97, wherein heat transfer fluid HTF1 heated by the photovoltaic-thermal solar energy collector has temperature T1 and heat transfer fluid HTF2 heated by the heat pump has temperature T2, and T2 is greater than T1.

101. The method of claim 97, wherein heat transfer fluid HTF1 heated by the photovoltaic-thermal solar energy collector has temperature T1 and heat transfer fluid HTF2 heated by the heat pump has temperature T2, and T1 is approximately equal to T2.

102. The method of claim 80, comprising using a heat transfer fluid HTF2 to collect heat h2 from the heat pump at a temperature T2 and then flowing heat transfer fluid HTF2 through one or more fluid channels in the photovoltaic solar thermal energy collector to collect heat h1 to thereby increase its temperature to a temperature T2′ greater than T2.

103-113. (canceled)

114. A system for generating dispatchable electrical energy, the system comprising:
one or more concentrating photovoltaic-thermal solar energy collectors comprising a reflector for focusing incident solar radiation on a receiver, the receiver comprising:
one or more photovoltaic cells that generate electrical energy e1; and
one or more fluid channels through which a heat transfer fluid HTF1 flows and collects heat h1 produced in the receiver;
a cold reservoir;
a heat pump driven at least in part by electrical energy e1 to draw heat h2 from the cold reservoir;
a hot reservoir to which heat h1 and heat h2 are transferred; and
a heat engine comprising an organic Rankine cycle engine for converting thermal energy in the hot reservoir to electrical energy e2.

115. (canceled)

116. The system of claim 114, comprising heat transfer fluid HTF2 heated by the heat pump to carry heat h2.

117. The system of claim 116, comprising a heat exchanger for transferring heat between heat transfer fluid HTF1 and heat transfer fluid HTF2.

118. The system of claim 116, wherein, in operation, heat transfer fluid HTF1 has a temperature T1 that is greater than a temperature T2 of heat transfer fluid HTF2.

119. The system of claim 116, wherein, in operation, heat transfer fluid HTF2 has a temperature T2 that is greater than a temperature Ti of heat transfer fluid HTF1.

120. (canceled)
